(19) United States
(12) Patent Application Publication
(10) Pub. No.: US 2011/0031452 A1
(43) Pub. Date: Feb. 10, 2011

(54) Nanoparticles Having Continuous Photoluminescence

(76) Inventors: Todd Krauss, Pittsford, NY (US); Megan Hahn, Nazareth, PA (US); Xiaoyong Wang, Rochester, NY (US)

Correspondence Address: HODGSON RUSS LLP;THE GUARANTY BUILDING, 140 PEARL STREET, SUITE 100, BUFFALO, NY, 14202-4040, US

(21) Appl. No.: 12/324,029

(22) Filed: Nov. 26, 2008

Related U.S. Application Data
(60) Provisional application No. 60/990,767, filed on Nov. 28, 2007.
(60) Provisional application No. 60/991,065, filed on Nov. 29, 2007.

(51) Int. Cl. H01B 1/02; H01L 21/20; B82Y 99/00

(52) U.S. Cl. 252/519.4; 252/519.51; 438/478; 977/773; 257/E21.09

(57) ABSTRACT

A nanoparticle comprising a ternary core comprising Cd, Zn and Se; and a shell comprising Zn and Y, wherein Y is Se or S or a combination thereof. The Cd and Zn are non-homogenously distributed in the ternary core such that the nanoparticle exhibits continuous photoluminescence for extended periods of time. Also provided are methods for preparing and methods of using the nanoparticles which exhibit continuous photoluminescence.

This application claims priority to U.S. Provisional application No. 60/990,767, filed on Nov. 28, 2007, and U.S. Provisional application No. 60/991,065, filed on Nov. 29, 2007, the disclosures of which are incorporated herein by reference.

This work was supported by funding from the U.S. Department of Energy under grant no. DE-FC26-06NT42864. The Government has certain rights in the invention.

### FIELD

The present disclosure relates to nanoparticles that continuously photoluminesce when irradiated by a source of electromagnetic radiation. The present disclosure further relates to methods for preparing continuously photoluminescent nanoparticles and methods of using continuously photoluminescent nanoparticles as biological markers, reporters, and analytical reagents.

### BACKGROUND

Semiconductor nanoparticles, such as CdSe quantum dots with diameters in the range of 1-7 nm, are important new materials that have a wide variety of applications, particularly in the biological arena. Of the many unique properties of these materials, the photophysical characteristics are some of the most useful. Specifically, these materials can display intense luminescent emission that is particle size-dependent and particle composition-dependent, can have an extremely narrow bandwidth, and can be environmentally insensitive; such emissions can be efficiently excited with electromagnetic radiation having a shorter wavelength than the highest energy emitter in the material. These properties allow for the use of semiconductor nanocrystals as ultra-sensitive luminescent reporters of biological states and processes in highly multiplexed systems.

Bare nanocrystals, i.e., nanocrystal cores, do not display sufficiently intense or stable emission, however, for these applications. In fact, the environments required for many applications can actually lead to the complete destruction of these materials. A key innovation that increases the usefulness of the nanocrystals is the addition of an inorganic shell over the core. The shell is composed of a material appropriately chosen to be preferably electronically insulating (through augmented redox properties, for example), optically non-interfering, chemically stable, and lattice-matched to the underlying material. This last property is important, since epitaxial growth of the shell is often desirable. Furthermore, matching the lattices, i.e., minimizing the differences between the shell and core crystallographic lattices, minimizes the likelihood of local defects, the shell cracking or forming long-range defects.

Considerable resources have been devoted to optimizing nanoparticle core synthesis. Much of the effort has been focused on optimization of key physiochemical properties in the resultant materials. For example, intense, narrow emission bands resulting from photo-excitation are commonly desirable. Physical factors impacting the emission characteristics include the crystallinity of the material, core-shell interface defects, surface imperfections or “traps” that enhance nonradiative deactivation pathways (or inefficient radiative pathways), the gross morphologies of the particles, and the presence of impurities. The use of an inorganic shell has been an extremely important innovation in this area, as its use has resulted in dramatic improvements in the aforementioned properties and provides improved environmental insensitivity, chemical and photochemical stability, reduced self-quenching characteristics, and the like.

Zhong et al., (See Zhong, X., et al., “Composition-Tunable ZnₓCd₁₋ₓSe Nanocrystals with High Luminescence and Stability” J. Am. Chem. Soc. (2003), 125, 8589-8594) disclose an alloy of cadmium, zinc, and selenium wherein the alloy is formed at an “alloy” temperature. The critical alloy temperature is determined by spectroscopically monitoring the emission spectrum of the alloy as it forms. As the core begins to alloy, the emission spectrum maximum begins to shift from longer to shorter wavelengths. Once the homogeneous alloy forms, there is a concomitant stop in the shift of the emission maxima.

Because of the nanoparticle size, the photostability, and the non-self-quenching of photoluminescence, a property that plagues dye molecules, the use of nanoparticles as biological markers to study cell processes and kinetics, as well as tools for biological assays, has been recognized. However, state of the art nanoparticles do not continuously photoluminesce, instead these particles “blink” or have discontinuous photoluminescence. This fact has consequences for the use of single nanoparticles as biological tracking tools. A nanoparticle used to track the progress of a cellular reaction that stops photoluminescing will leave a gap in the thermodynamic, as well as the kinetic aspects of the observed cellular reaction. In addition, it is sometimes not known if a blinking nanoparticle that once again begins to photoluminesce is the same nanoparticle when more than one blinking quantum dot is present in the cell being studied.

There is therefore a long felt need for nanoparticles that do not blink and thereby cause a loss of information to the user. There is also a long felt need for continuously photoluminescent nanoparticles that have a biologically compatible coating or a coating that can be modified for biocompatibility. There is also a need for nanoparticles that continuously photoluminesce wherein the properties of the nanoparticle, inter alia, photo efficiency, emission wavelength, absorption wavelength, and shape can be controlled.

### SUMMARY

The present invention provides a nanoparticle comprising a ternary core comprising Cd, Zn and Se; and a shell comprising Zn and Y, wherein Y is Se or S or a combination thereof. The Cd and Zn are non-homogenously distributed in the ternary core such that the photoluminescence exhibited by the nanoparticle is continuous as determined by a lack of correlation between fluctuations in photoluminescence intensity over a period of time such as at least 200 seconds. In one aspect, the photoluminescence was found to be continuous over a period of at least 4 hours. The opto-electronic behavior of the nanoparticles of the present invention is consistent with the nanoparticles having a graded composition such that there exists a gradient of cadmium and zinc atom concentration within the ternary core. Generally, the cadmium atom concentration decreases from the center to the outer edge of the ternary core; and the zinc atom concentration increases from the center to the outer edge of the ternary core.

The present invention also provides compositions comprising the continuously photoluminescent nanoparticles having an average size of between 1 and 100 nm. In one aspect, the average diameter is between 2 and 7 nm.

The invention further provides a method for preparing nanoparticles which exhibit continuous photoluminescence. The method comprises the steps of: providing CdSe binary cores; adding, at least twice, alternately to the cores of a), a source of zinc capable of reacting with the CdSe binary core and a source of selenium capable of reacting with the CdSe binary core at a temperature sufficient to form a ternary core; c) holding the cores from b) at a temperature and time sufficient for obtaining CdZnSe ternary cores; and d) adding to the CdZnSe ternary cores a source of Zn and a source of Y to form a nanoparticle comprising a ternary core and a ZnY shell, wherein Y is Se, S or a combination thereof. In one aspect of the invention, the alternate addition of Zn and Se is carried out at least three times or at least four times.

The disclosed nanoparticles are suitable for use in thin-film light emitting devices (LEDs), low-threshold lasers, optical amplifier media for telecommunication networks, for relay of encrypted information, as well as biological labels.

### BRIEF DESCRIPTION OF THE FIGURES

FIG. 1 depicts the proposed manner in which the coordinating solvent can associate with the atoms on the surface of a nanoparticle. FIG. 1 depicts the association of a molecule of tri-n-octylphosphine oxide with a cadmium or selenium atom on the surface of the CdSe binary core.

FIG. 2 depicts the absorption spectrum of a disclosed CdₓZn₁₋ₓSe/ZnSe nanoparticle as prepared according to Example 2.

FIG. 3 depicts the photoluminescence spectrum (linear scale) of the disclosed CdₓZn₁₋ₓSe/ZnSe nanoparticle as prepared according to Example 2.

FIG. 4 depicts the photoluminescence spectrum (logarithmic scale) of the disclosed CdₓZn₁₋ₓSe/ZnSe nanoparticle as prepared according to Example 2.

FIG. 5 shows the continuous photoluminescence of a disclosed CdₓZn₁₋ₓSe/ZnSe nanoparticle prepared according to Example 2. The spectrum was taken from a sample wherein the nanoparticle was embedded in a poly(methyl methacrylate) film onto a quartz substrate and excited at 532 nm with a laser beam.

FIG. 6 shows the continuous photoluminescence of a disclosed CdₓZn₁₋ₓSe/ZnSe nanoparticle prepared according to Example 2 is continuous until photobleached by a 10 kW/cm² radiation source.

FIG. 7 shows the non-continuous photoluminescence of a commercially available single CdSe nanoparticle.

FIG. 8 shows a histogram of photon coincidence counts for the time delays between two consecutive photons emitted from a disclosed CdₓZn₁₋ₓSe/ZnSe nanoparticle prepared according to Example 2.

FIG. 9 shows a histogram of photon coincidence counts for the time delays between two consecutive photons emitted from a prior art CdTe nanoparticle.

FIG. 10 shows a histogram of photon coincidence counts for the time delays between two consecutive photons emitted from a commercially available CdSe nanoparticle whose non-continuous photoluminescence is depicted in FIG. 7.

FIG. 11 depicts an enzyme attached to a disclosed nanoparticle by way of a linking group (L).

FIG. 12 depicts the conjugation of a biological analyte to the passivation layer of a continuously photoluminescent nanoparticle using a lipid bilayer approach.

FIG. 13 (a) depicts the non-continuous photoluminescent intensity from commercially available CdSe/ZnSe nanocrystals; (b) depicts the continuous photoluminescent intensity from CdZnSe/ZnSe nanocrystals of the present invention; (c) depicts the auto correlation function over time for photoluminescent intensity for nanocrystals of (a) and nanocrystals of (b).

FIG. 14 depicts the photoluminescent intensity versus time traces for a single CdZnSe/ZnSe NC bleached after 35 s of laser illumination. The binning times used are (A) 1 ms, (B) 5 ms, and (C) 10 ms, respectively.

FIG. 15. (A) PL spectra of five selected single CdZnSe/ZnSe NCs. (B) PL spectrum of a single standard CdSe/ZnS NC. (C) Diagram of a shake-up process used to explain the multi-peaked PL spectrum from a single CdZnSe/ZnSe NC. The annihilation energy of the positively charged exciton (spacing between two dashed lines) is distributed between the emitted photon energy (shown by the arrows) and the energy of the extra hole, which could occupy one of many allowed levels after recombination. The allowed levels are calculated assuming a parabolic, axially symmetric potential. The relative intensities of the “shake-up line” are proportional to the overlap of the wave functions of the extra hole in the charged exiton and by itself in the confinement potential.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which need to be independently confirmed.

Throughout the description and claims of this specification the term “comprise” and other forms of the term, such as “comprising” and “comprises,” means including but not limited to, and is not intended to exclude, for example, other elements, additives, components, integers, or steps. Thus, such terms are inclusive or open-ended transitional terms and do not exclude additional, unrecited elements, additives, components, integers, or steps. In one aspect, these terms are synonymous with “having,” “including,” “containing,” or “characterized by.”

As used herein, the terms “consisting essentially of” or “consists essentially of” are generally open-ended transitional terms, but limit the scope of a claim to the specified materials or steps and those that do not materially affect the basic and novel characteristic(s) of the claimed invention.

As used in the description and the appended claims, the singular forms “a,” “an,” and “the” include plural referents unless the context clearly dictates otherwise. Thus, for example, reference to “a nanoparticle” includes mixtures of two or more such nanoparticles.

“Optional” or “optionally” means that the subsequently described component, event or circumstance can or cannot occur, and that the description includes instances where the component, event or circumstance occurs and instances where it does not.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that when a value is disclosed, then “less than or equal to” the value, “greater than or equal to the value,” and possible ranges between values are also disclosed, as appropriately understood by the skilled artisan. For example, if the value “10” is disclosed, then “less than or equal to 10” as well as “greater than or equal to 10” is also disclosed. It is also understood that throughout the application data are provided in a number of different formats and that this data represent endpoints and starting points and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units is also disclosed. For example, if 10 and 15 are disclosed, then 11, 12, 13, and 14 are also disclosed.

“Nanoparticle,” “nanocrystal,” “quantum dot,” and “quantum dot nanocluster” are used interchangeably throughout the disclosure to describe the CdSe binary cores, CdₓZn₁₋ₓSe ternary cores, and final CdₓZn₁₋ₓSe/ZnSe, CdₓZn₁₋ₓSe/ZnS, and CdₓZn₁₋ₓSe/ZnSe,S continuously photoluminescent nanoparticles.

“Biological analyte” means any protein, peptide, enzyme, nucleotide, factor, antigen, antibody, and the like that participates in a biological function in vivo, in vitro, or ex vivo. The biological analyte when attached to or otherwise associated with a disclosed nanoparticle is thereby “conjugated” with the nanoparticle and thereby forms a “biological conjugate.”

“Quantum efficiency” means the percentage of photons encountering the disclosed nanoparticle that will produce a fluorescing electron-hole pair. Thus, in one aspect, quantum efficiency can be expressed in terms of photons emitted as a function of photons absorbed.

The term “photoluminescence” or “photoluminescent” denotes the emission of electromagnetic radiation (light) from the disclosed nanoparticles. Photoluminescence results from a system that is “relaxing” from an excited state to a lower state with a corresponding release of energy in the form of a photon. These states can be electronic, vibronic(vibrational), rotational, or any combination of these three. The transition responsible for photoluminescence can be stimulated through the release of energy stored in the system chemically or added to the system from an external source, for example, by irradiation by an electromagnetic source. In addition, the external source of energy can be of a variety of types including chemical, thermal, electrical, magnetic, physical, or any other type excited by absorbing a photon of light, by being placed in an electric field, or through a chemical oxidation-reduction reaction. The energy of the photons emitted during luminescence can be in a range of far-infrared to ultraviolet radiation.

The term “substantially monodisperse” when describing continuously photoluminescent nanoparticles denotes a population of nanoparticles of which a major portion, typically at least about 60%, in another aspect from 75% to 90%, fall within a specified particle size range. A population of substantially monodisperse nanoparticles deviates 15% rms (root-mean-square) or less in diameter and typically less than 5% rms. In addition, upon exposure to a primary light source, a substantially monodisperse population of continuously photoluminescent nanoparticles is capable of emitting energy in narrow spectral linewidths, as narrow as 12 nm to 60 nm full width of emissions at half maximum peak height (FWHM), and with a symmetric, nearly Gaussian line shape. The formulator will recognize, the linewidths are dependent on, among other things, the size heterogeneity, i.e., monodispersity, of the semiconductor nanocrystals in each preparation

As used herein, the term “homogeneous core” refers to CdₓZn₁₋ₓSe ternary cores wherein the distribution of cadmium and zinc atoms is homogeneous throughout the ternary core. The terms “amalgam” and “alloy” are used interchangeably throughout the specification to describe homogeneous nanoparticle cores.

As used herein, the term “non-homogeneous core” refers to CdₓZn₁₋ₓSe ternary cores wherein there exists a gradient of cadmium and zinc atom concentration within the ternary core. Generally, the cadmium atom concentration decreases from the center (first end of the gradient) to the outer edge (second end of the gradient) of the ternary core; and the zinc atom concentration increases from the center to the outer edge of the ternary core. In one aspect, the cadmium and zinc atom concentrations are radially graded. The term “radially graded” means that the concentration of Cd relative to Zn is constant on a sphere (which has a constant radius).

The present invention provides a nanoparticle comprising a ternary core and a shell. The ternary core comprises Cd, Zn and Se, and the shell comprises ZnY, wherein Y is Se, S or a combination thereof. The Cd and Zn are non-homogenously distributed in the ternary core such that the photoluminescence exhibited by the nanoparticle is continuous as determined by a lack of correlation between fluctuations in photoluminescence intensity over extended periods of time. Nanoparticles of the present invention exhibit continuous photoluminescence without the need for thiol containing chemicals.

In one aspect, the disclosed continuously photoluminescent nanoparticles comprise:
a) a ternary core having the formula CdₓZn₁₋ₓSe wherein 0.001<x<0.999; and
b) a shell chosen from ZnSe, ZnS, or a mixture thereof.

In one aspect the disclosed continuously photoluminescent nanoparticles comprise:
a) a ternary core having the formula CdₓZn₁₋ₓSe wherein 0.1<x<0.9; and
b) a shell chosen from ZnSe, ZnS, or a mixture thereof;
wherein the ternary core comprises a continuous gradient of cadmium and zinc atoms, the first end of the gradient beginning at the center of the ternary core and the second end of the gradient being on the outside edge of the ternary core, and wherein further the first end of the gradient comprises greater than 50% cadmium atoms and the second end of the gradient comprises greater than 50% zinc atoms.

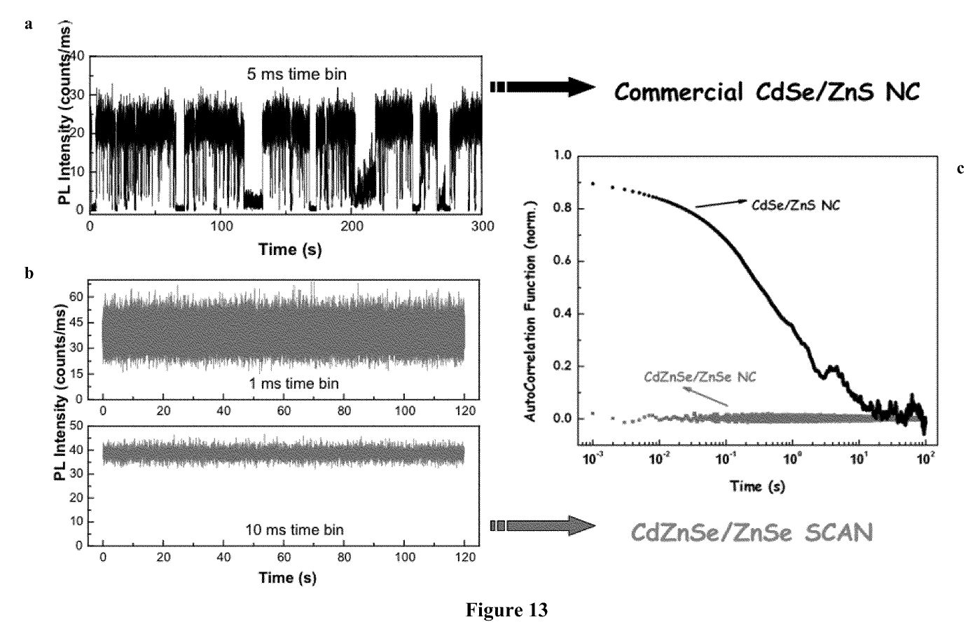

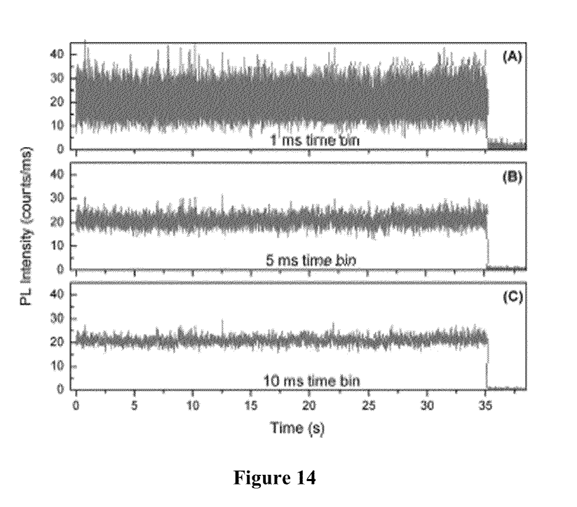

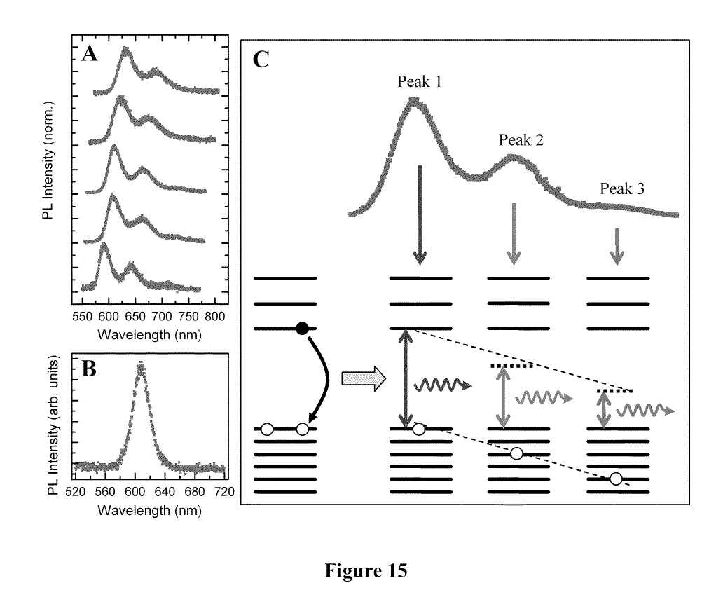

The nanoparticles of the present invention are continuously photoluminescent (also referred to herein as non-blinking). Continuous photoluminescence is defined as nanoparticle photoluminescent emission with no blinking (i.e. no “off”, or dark time, or no significant changes in “on” intensity), as determined by a lack of correlation between fluctuations in photoluminescent intensity. The lack of correlation demonstrates that the intensity fluctuations in the luminescence signal arise from purely statistical noise. Put another way, no intensity fluctuation is correlated (or related) to any other intensity fluctuation over any given time period. (See FIG. 13) For blinking nanoparticles that are not continuously photoluminescent (e.g. commercially available CdSe/ZnS nanoparticles) fluctuations in photoluminescent intensity exhibit correlations. (See FIG. 13).

The nanoparticles of the present invention can continuously photoluminesce over extended periods of time. For example, such nanoparticles exhibit continuous photoluminescence from 4.1 ns, the excited state lifetime, to at least 4 hours. In various aspects of the present invention the nanoparticles of the present invention continuously photoluminesce for at least up to 100 microseconds, 1 millisecond, 1, 5, 10, 30, 60, 100, 200, 250, 500, 1000, 1500, 2000, 2500, and 3600 seconds, and at least up to 1.5, 2.0, 2.5, 3.0, 3.5 and 4.0 hours. In addition, the continuous photoluminescence times specified above include all integers between the times and all fractions of those times, for microseconds, milliseconds, seconds and hours.

In one aspect, the first end of the gradient (center or core of the nanoparticle ternary core) comprises greater than 60% cadmium atoms and the second end of the gradient (the outside of the ternary core) comprises greater than 60% zinc atoms. In another aspect, the first end of the gradient comprises greater than 70% cadmium atoms and the second end of the gradient comprises greater than 70% zinc atoms. In a further aspect, the first end of the gradient comprises greater than 80% cadmium atoms and the second end of the gradient comprises greater than 80% zinc atoms. In a yet further aspect, the first end of the gradient comprises greater than 90% cadmium atoms and the second end of the gradient comprises greater than 90% zinc atoms. In a still further aspect, the first end of the gradient comprises 100% cadmium atoms and the second end of the gradient comprises 100% zinc atoms.

In another aspect, the cadmium and zinc atom gradients (which define the change in composition of the ternary core from the first end of the gradient to the second end of the gradient) can be described by a smooth function that is decreasing in the case of Cd and increasing in the case of Zn. Examples of such functions include all trigonometric functions, polynomials, exponentials, and all sums and products thereof.

Without intending to be bound by any particular theory, the opto-electronic behavior of the nanoparticles of the present invention can be explained by a theoretical model based on the nanoparticles having a graded composition. The graded alloy nanoparticle core provides a smooth or gradually changing confinement potential for electrons and holes. This potential avoids any singularities and drastically reduces the probability for extra electrons or holes to pick up the annihilation energy of an electron-hole pair and transfer it to kinetic energy. The transfer of the annihilation energy of an electron-hole pair to kinetic energy of an extra charge is called Auger recombination, and is a nonradiative process. Nanoparticles are essentially non-emissive when charged, if these nonradiative Auger processes are efficient. We considered a parabolic and axially symmetric confinement potential for electrons and holes in the CdZnSe/ZnSe alloyed core/shell QDs. This potential is an excellent model for a graded alloyed core, as it contains no singularities in the potential function or its derivatives. In other words, the potential is smooth with no jumps or kinks. For such a potential, Auger processes are drastically weakened, and we calculated that nanoparticles will emit light whether charged or neutral. In other words, their luminescence intensity is constant. We calculated the luminescence characteristics of a positively charged exciton (i.e. 2 holes and one electron) in a parabolic, axially symmetric potential and found that this model explained the short radiative lifetime of ˜4 ns, and the three-peaked luminescence spectrum, including the relative magnitude of the three peaks.

The observation of charged emission lines in the photoluminescence spectrum is significant. Normally a charged exciton would not emit light, due to strong Auger (i.e. nonradiative) processes. Therefore, the observation of charged emission lines leads to the conclusion that in these graded alloy-core nanocrystals the Auger processes are relatively weak. A weak Auger process means that a charged nanoparticle does not have any “off” periods of the photoluminescence, which is what is observed via the non-blinking nature of the photoluminescence. The nanoparticle is continuously emitting (i.e. always “on”) whether it is charged or neutral.

However, a formulator can adjust the stoichiometry of cadmium and zinc and the conditions outlined herein below to form nanoparticles having, for example, the first end of the gradient comprising greater than 20% cadmium atoms and the second end of the gradient comprises greater than 90% zinc atoms.

The disclosed nanoparticles, quantum dots, and quantum dot nanoclusters provide a method for detecting, tracking, analyzing, modifying, and otherwise studying biological processes in vivo, in vitro, and ex vivo. The disclosed quantum nanoparticles, quantum dots, and quantum dot clusters provide the following non-limiting examples of biological and/or microbiological-related uses:

As probes for determining the presence or function of a biological analyte;

As a method for continuously tracking the movement of a biological analyte in a cell;

As a method for continuously tracking the effect on a biological analyte in a cell when a biological effector is added to the cell;

A method for continuously tracking biological interaction of a biological analyte in a cell;

A method for continuously tracking the interaction of a biological analyte and a biological effector in a cell;

As well as, other similar uses and methods as further described herein below.

The disclosed continuously photoluminescent nanoparticles are comprised of a core and a shell. In one aspect, the average diameter of the disclosed nanoparticles is less than about 100 nanometers. In a further aspect, the average diameter is less than about 50 nanometers. In a still further aspect, the average diameter is less than about 25 nanometers. Non-limiting examples of the continuously photoluminescent nanoparticles disclosed herein have average diameters of 5 nanometers, 6 nanometers, 7 nanometers, 8 nanometers, 9 nanometers, 10 nanometers, 11 nanometers, and 12 nanometers. However, the average diameter can be a fractional amount, for example, 5.1 nanometers, 6.25 nanometers, and 7.553 nanometers. In one aspect, the average diameter of the nanoparticles is between 2 nm and 7 nm in size.

Preferably, the nanoparticles are substantially monodisperse. For example, the deviation in size distribution of fully alloyed core-shell nanoparticles is 15% in length and width as measured by transmission electron microscopy. Generally, the cores have a smaller size deviation of less than 10% in rms, and typically less than 5%.

The shape of the nanoparticles can be other than spherical, for example, the nanoparticles can be “tablet-shaped” similar to a common pill, for example, an aspirin. The nanoparticles can also be ovoid, ellipsoid, or have an irregularly shaped outer shell.

### Methods of Making

Disclosed are methods for making and using continuously luminescent nanoparticles. It is understood that the disclosed methods can be used in connection with the disclosed compositions. In one aspect, the invention relates to methods of preparing nanoparticles and the various components of nanoparticles.

In one aspect the present invention provides a process for preparing CdZnSe ternary cores, comprising the steps of: a) providing CdSe binary cores; b) adding, at least twice, alternately to the cores of a), a source of zinc capable of reacting with the CdSe binary core and a source of selenium capable of reacting with the CdSe binary core at a temperature sufficient to form a ternary core; c) holding the cores from b) at a temperature and time sufficient for obtaining CdₓZn₁₋ₓSe ternary cores; and d) adding to the CdₓZn₁₋ₓSe ternary cores a source of Zn and a source of Y to form a shell, ZnY, wherein Y is Se, S or a combination thereof. The source of zinc and the source of selenium in step b) is carried out at least twice so that the sequence is: Zn source addition, Se source addition, Zn source addition Se source addition, etc. While the addition of the Zn source and the Se source is alternated, the sequence can be initiated by the addition of either source.

Preparation of Cdse Binary Core

An initial step relates to the formation of the initial CdSe binary core. The disclosed process comprises formation of CdSe binary cores comprising:
i) combining a source of Cd in a form suitable for forming a binary core and a source of Se in a form suitable for forming a binary core at a temperature sufficient to initiate formation of a CdSe binary core; and
ii) growing the CdSe binary cores.

However, CdSe binary cores are commercially available, and these commercially available cores can be used to form the ternary cores disclosed herein below, provided the resulting shelled cores are continuously photoluminescent. As such the present disclosure also provides for the preparation of the CdSe binary cores.

One aspect of formation of CdSe binary cores comprises formation of a CdSe binary core comprising:
i) combining a source of Cd in a form suitable for forming a binary core and a source of Se in a form suitable for forming a binary core at a temperature, T¹, sufficient to form a CdSe binary core nucleus; and
ii) growing the CdSe binary core at a temperature T².

A further aspect of step (a) comprises:
i) providing a source of Cd in a form suitable for forming a binary core;
ii) providing a source of Se in a form suitable for forming a binary core;
iii) combining the source of Cd and the source of Se to form a reaction solution;
iv) heating the reaction solution to a temperature of from about 290° C. to about 360° C. to form a plurality of CdSe nucleates;
v) cooling the CdSe nucleates to a temperature of from about 240° C. to about 270° C. and thereby forming from the CdSe nucleates a plurality of CdSe binary cores;
vi) further cooling the CdSe binary cores to stop the growth of the binary cores.

A yet further aspect of formation of CdSe binary cores comprises:
a) formation of CdSe binary cores comprising:
   i) combining a source of Cd in a form suitable for forming a binary core and a source of Se in a form suitable for forming a binary core at a temperature T¹ to initiate formation of a CdSe binary core;
   ii) cooling the CdSe binary core to a temperature T² and further growing the binary core.

Formation of CdSe binary cores encompasses combining a source of cadmium and selenium that is suitable for forming a CdSe binary core. The source of cadmium can be any source that is capable of reacting and thereby forming a CdSe binary core, for example, CdO or cadmium combined with a ligand. Non-limiting examples of ligands include an organic acid, an organic amine, an alkylphosphonic acid, an arylphosphonic acid, an alkylphosphine oxide, an arylphosphine oxide, and the like. The source of selenium can be any source that is capable of reacting and thereby forming a CdSe binary core, for example, selenium metal or selenium combined with a ligand. Non-limiting examples of ligands include an organic acid, an organic amine, an alkylphosphonic acid, an arylphosphonic acid, an alkylphosphine oxide, an arylphosphine oxide, and the like.

Once the source of cadmium and selenium are combined to form an admixture, the admixture is heated to a temperature, T¹, which is sufficient to begin the formation of the CdSe binary core. Raising the admixture to a temperature, T¹, begins the formation of CdSe nucleates. The formulator can allow the formation of nucleates to continue to form for any period of time sufficient to achieve final nanoparticles having the properties desired by the formulator.

In one aspect, the admixture is heated to a temperature of from about 290° C. to about 360° C. to form the CdSe nucleates. In another aspect, the admixture is heated to a temperature of from about 290° C. to about 330° C. In a further aspect, the admixture is heated to a temperature of from about 290° C. to about 310° C.

The CdSe binary cores, once nucleation occurs, are grown at a temperature T². The size of the core can be adjusted by the formulator by varying T². Once the source of cadmium is combined with the source of selenium, the temperature of the reaction is reduced to the growth temperature, T², for from 30 seconds to about 1 hour. However, rapid growth of the binary core begins to slow within 30 minutes and longer annealing times serve to provide differences in shape (more spherical or more rodlike) to the binary core. In one aspect the growth time is from 1 minute to 10 minutes. In a further aspect, the growth time is from 1 minute to 7 minutes. In another aspect, the growth time is from 3 minutes to 7 minutes. In a yet another aspect, the growth time is from 4 minutes to 8 minutes. In a still yet another aspect, the growth time is 30 seconds to 3 minutes. However, the growth time can be any time chosen by the formulator, for example, 1 minute, 2 minutes, 3 minutes, 4 minutes, 5 minutes, 6 minutes, 7 minutes, 8 minutes, 9 minutes, 10 minutes, and the like. In addition, the time can be measured in seconds when fractional parts of minutes are used for the growth time, for example, 30 seconds, 90 seconds, 115 seconds, 212 seconds, 250 seconds, and the like. The formulator can continue the growth time beyond 1 hour to take advantage of Oswald ripening in order to form highly uniform particle sizes.

In addition to varying the growth time, a further parameter that can be adjusted by the formulator to produce continuously photoluminescent nanoparticles is the temperature of growth. The binary cores can be grown at a temperature, T², from about 240° C. to about 270° C. In one aspect, the growth temperature is from about 250° C. to about 260° C. In another aspect, the growth temperature is from about 240° C. to about 260° C. In a further aspect, the growth temperature is from about 250° C. to about 270° C. In yet a further aspect, the growth temperature is from about 240° C. to less than about 270° C. In still a further aspect, the growth temperature is from about 250° C. to about 265° C. However, the growth temperature can have any discrete temperature value, for example, 250° C., 251° C., 252° C., 253° C., 254° C., 255° C., 256° C., 257° C., 258° C., 259° C., and the like. In another aspect, the growth temperature can be varied during the growth process, for example, a temperature ramp from less than about 270° C. to about 240° C. Or alternatively, a ramp from lower temperature to higher temperature, for example, a temperature ramp from about 240° C. to less than about 270° C. The temperature ramp can be accomplished at any rate, for example, from about 0.1° C./minute to about 10° C./minute. In addition, the ramp may take place during any time interval of the growth process, for example, a growth step that is held at a first temperature for a predetermined period and then ramped to a higher or lower temperature during the balance of the time allotted for the growth step.

The preparation of the binary core can be conducted in the presence of a particle growth, nucleation stabilization system (PGNSS). In one aspect, the PGNSS comprises an alkyl amine, for example, an alkyl amine chosen from octylamine, nonylamine, decylamine, undecylamine, dodecylamine (laurylamine), tridecylamine, tetradecylamine (myristyl amine), pentadecylamine, hexadecylamine (palmitylamine), septadecylamine, octadecylamine, and the like. In addition, unsaturated amines can be used in this aspect, for example, an amine chosen from Δ²-dodecenylamine, (Z)-Δ⁹-tetradecenylamine, (Z)-Δ⁹-hexadecenylamine, (Z)-Δ⁹-octadecenylamine (oleylamine), (Z,Z)-Δ^{9,12}-octadecadienylamine (linoleylamine), (Z,Z,Z)-Δ^{9,12,15}-octadecatrienylamine (linolenylamine), (Z)-Δ¹¹-eicosenylamine, (Z,Z,Z)-Δ^{5,8,11}-eicosatrienylamine, and (Z)-Δ¹³-docosenylamine.

Another aspect of the PGNSS comprises a nucleation modifier. The effect of the nucleation modifier is to control the rate of crystal growth in a way that inhibits assembly of the binary core from being too rapid, but instead allows an orderly assembly of the atoms, and, therefore, a narrow particle size distribution. Non-limiting examples of nucleation modifiers include hexylphosphonic acid, heptylphosphonic acid, octylphosphonic acid, nonylphosphonic acid, decylphosphonic acid, undecylphosphonic acid, dodecylphosphonic acid, and tetradecylphosphonic acid. In one aspect, the nucleation modifier is the phosphonic acid corresponding to the chain length of a phosphine oxide solvent. For example, when tri-n-octylphosphine oxide is used as a solvent or co-solvent, the use of octylphosphonic acid as the nucleation inhibitor provides for control over binary core particle size distribution. However, as seen in Example 2 herein below, the use of tetradecylphosphonic acid with tri-n-octylphosphine oxide results in control of binary core particle size.

The nanoparticle binary cores are formed in the presence of one or more coordinating solvents. The choice of coordinating solvent can affect the final properties of the continuously photoluminescent nanoparticles. Coordinating solvents serve several purposes, for example, they coat the binary core with a uniform layer thereby removing the maximum of dangling electron bonds/surface states that are responsible for fluorescence trapping and photooxidation, they are capable of solubilizing the formed binary cores, and because of their relatively high boiling points, allow formation for the binary cores at high temperatures, for example, from about 290° C. to about 360° C.

Among the different types of coordinating solvents that can be used are alkylphosphines, alkylphosphine oxides, alkylphosphites, alkylphosphates, alkylamines, alkylphosphonic acids, alkylethers, alkylcarboxylic acids, and the like. Solvents suitable for use in preparing the disclosed binary cores include solvents chosen from trioctylphosphine, tributylphosphine, tri(dodecyl)-phosphine, trioctylphosphine oxide, dibutyl-phosphite, tributyl phosphite, trioctadecyl phosphite, trilauryl phosphite, tris(tridecyl) phosphite, triisodecyl phosphite, bis(2-ethylhexyl)phosphate, tris(tridecyl) phosphate, hexadecylamine, oleylamine, octadecylamine, bis(2-ethylhexyl)amine, octylamine, dioctylamine, trioctylamine, dodecylamine (laurylamine), didodecylamine, tridodecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, octanoic acid, nonanoic acid, decanoic acid, undecanoic acid, dodecanoic acid (lauric acid), tridecanoic acid, tetradecanoic acid (myristic acid), pentadecanoic acid, hexadecanoic acid (palmitic acid), septadecanoic acid, octadecanoic acid (stearic acid), (Z)-Δ⁹-octadecenoic acid (oleic acid), (Z,Z)-Δ^{9,12}-octadecadienoic acid (linolenic acid), (Z,Z,Z)-Δ^{9,12,15}-octadecatrienoic acid (linolenic acid), dioctylether, dioctyl ether/octyl ether, dodecyl ether, hexadecyl ether, octadecyl ether, and octadecene.

Admixture of a coordinating solvent with an alkyl amine nucleation modifier can provide a better surface for the binary cores in addition to the final continuously photoluminescent nanoparticles: CdₓZn₁₋ₓSe/ZnSe, CdₓZn₁₋ₓSe/ZnS, and CdₓZn₁₋ₓSe/ZnSe,S.

The ratio of cadmium to selenium used to form the CdSe binary cores can be from about 1:1 to about 1:10 wherein the amount of selenium is in excess. In another aspect, the ratio is from about 1:2 to about 1:10 wherein the amount of selenium is in excess. In a further aspect, the ratio is from about 1:3 to about 1:5 wherein the amount of selenium is in excess. In one example, the ratio of cadmium to selenium is about 1:4 wherein the amount of selenium is in excess. In another example, the ratio of cadmium to selenium is about 1:3 wherein the amount of selenium is in excess. In a further example, the ratio of cadmium to selenium is about 1:5 wherein the amount of selenium is in excess. Alternatively, the amount of cadmium can be in excess relative to the amount of selenium.

The above description provides CdSe binary cores suitable for preparing the ternary cores. Commercially available CdSe binary cores can be produced by methods that are not compatible with the disclosed processes for preparing the continuously photoluminescent nanoparticles.

Preparation of CdₓZn₁₋ₓSe Ternary Core

Another step relates to formation of the CdₓZn₁₋ₓSe ternary core. The ternary cores disclosed herein are not homogeneous cores. True amalgams or alloys comprise a homogeneous mixture of cadmium, zinc, and selenium. The nanoparticles disclosed herein do not comprise fully alloyed or amalgamated ternary cores. The ternary cores disclosed herein exhibit continuous photoluminescence and are considered to have a continuous differential concentration gradient of cadmium and zinc atoms from the center to the outside of the ternary core. In one aspect, the center of the core essentially comprises CdSe whereas the outside edge of the core essentially comprises ZnSe.

The disclosed process comprises formation of CdₓZn₁₋ₓSe ternary cores comprising:
i) providing a source of a CdSe binary core;
ii) providing a source of zinc capable of reacting with the CdSe binary core; iii) providing a source of selenium capable of reacting with the CdSe binary core;
iv) adding at a temperature sufficient to form a ternary core the source of zinc;
v) adding at a temperature sufficient to form a ternary core the source of selenium;
vi) repeating step (iv) and step (v); and
vii) growing the CdₓZn₁₋ₓSe ternary cores.

In a further aspect, the process comprises formation of CdₓZn₁₋ₓSe ternary cores comprising:
i) providing a source of a CdSe binary core at a temperature, T³;
ii) providing a source of zinc capable of reacting with the CdSe binary core;
iii) providing a source of selenium capable of reacting with the CdSe binary core;
iv) adding at temperature, T³, the source of zinc;
v) adding at temperature, T³, the source of selenium;
vi) repeating step (iv) and step (v); and
vii) growing the CdₓZn₁₋ₓSe ternary cores at a temperature, T⁴.

In another aspect, the process comprises formation of CdₓZn₁₋ₓSe ternary cores comprising:
i) providing a source of a CdSe binary core at a temperature, T³;
ii) providing a source of zinc capable of reacting with the CdSe binary core;
iii) providing a source of selenium capable of reacting with the CdSe binary core; iv) adding at temperature, T³, the source of zinc;
v) adding at temperature, T³, the source of selenium;
vi) repeating step (iv) and step (v) more than once; and
vii) growing the CdₓZn₁₋ₓSe ternary cores at a temperature, T⁴.

In a yet further aspect, the process comprises formation of CdₓZn₁₋ₓSe ternary cores comprising:
i) providing a source of a CdSe binary core at a temperature, T³;
ii) providing a source of zinc capable of reacting with the CdSe binary core;
iii) providing a source of selenium capable of reacting with the CdSe binary core;
iv) adding at temperature, T³, the source of zinc;
v) adding at temperature, T³, the source of selenium;
vi) repeating step (iv) and step (v);
vii) growing the CdₓZn₁₋ₓSe ternary cores at a temperature, T⁴; and
viii) cooling the CdₓZn₁₋ₓSe ternary cores.

Step (b) encompasses combining a source of zinc and selenium that is suitable for forming a CdₓZn₁₋ₓSe ternary core from a CdSe binary core. The source of zinc can be any source that is capable of reacting and thereby forming a CdₓZn₁₋ₓSe ternary core, for example, zinc combined with a ligand. Non-limiting examples of ligands include C₁-C₂₀ linear, branched or cyclic alkyl moieties, an organic acid, an organic amine, an alkylphosphonic acid, an arylphosphonic acid, an alkylphosphine, an arylphosphine, an alkylphosphine oxide, an arylphosphine oxide, and the like. The source of selenium can be any source that is capable of reacting and thereby forming a CdₓZn₁₋ₓSe ternary core, for example, selenium combined with a ligand. Non-limiting examples of ligands includes an organic acid, an organic amine, an alkylphosphonic acid, an arylphosphonic acid, an alkylphosphine, an arylphosphine, an alkylphosphine oxide, an arylphosphine oxide, and the like.

The sources of zinc and selenium are added to the CdSe binary core at a temperature, T³. The sources of zinc and selenium are added alternatively with the source of zinc being added first, for example, a source of zinc is added followed by addition of a source of selenium. In one aspect, the addition steps are repeated one time. In another aspect, the addition steps are repeated two times. In a further aspect, the addition steps are repeated three times. In a still further aspect, the addition steps are repeated four times. In a yet still further aspect, the addition steps are repeated five times.

In one aspect, T³ is from about 270° C. to about 300° C. to cause the zinc and selenium sources to react with the CdSe binary cores. In another aspect, T³ is from about 280° C. to about 290° C. In a further aspect, T³ is from about 285° C. to about 300° C. In one example, T³ is 300° C.

Once the sources of zinc and selenium are added, the reaction is lowered to a growing or an annealing temperature T⁴. The reaction can be held at the annealing temperature, T⁴, for from 30 seconds to about 1 hour. In one aspect the annealing time is from 1 minute to 10 minutes. In a further aspect, the annealing time is from 1 minute to 7 minutes. In another aspect, the annealing time is from 3 minutes to 7 minutes. In yet another aspect, the annealing time is from 4 minutes to 8 minutes. In still yet another aspect, the annealing time is 30 seconds to 3 minutes. However, the annealing time can be any time chosen by the formulator, for example, 1 minute, 2 minutes, 3 minutes, 4 minutes, 5 minutes, 6 minutes, 7 minutes, 8 minutes, 9 minutes, 10 minutes, and the like. In addition, the time can be measured in seconds when fractional parts of minutes are used for the annealing time, for example, 30 seconds, 90 seconds, 115 seconds, 212 seconds, 250 seconds, and the like.

In addition to varying the annealing time, a further parameter that can be adjusted by the formulator to produce continuously photoluminescent nanoparticles is the temperature of annealing. The ternary cores can be annealed at a temperature, T⁴, from about 270° C. to about 310° C. In one aspect, the annealing temperature is from about 280° C. to about 300° C. In another aspect, the annealing temperature is from about 290° C. to about 295° C. In a further aspect, the annealing temperature is from about 275° C. to about 295° C. In yet a further aspect, the annealing temperature is from about 285° C. to 310° C. In a still further aspect, the annealing temperature is from about 270° C. to about 300° C. However, the annealing temperature can have any discrete temperature value, for example, 270° C., 271° C., 272° C., 273° C., 274° C., 275° C., 276° C., 277° C., 278° C., 279° C., and the like. In another aspect, the annealing temperature can be varied during the annealing process, for example, a temperature ramp from less than about 300° C. to about 270° C. Or alternatively, a ramp from lower temperature to higher temperature, for example, a temperature ramp from about 270° C. to less than about 300° C. The temperature ramp can be accomplished at any rate, for example, from about 0.1° C./minute to about 10° C./minute. In addition, the ramp may take place during any time interval of the annealing process, for example, an annealing step that is held at a first temperature for a predetermined period and then ramped to a higher or lower temperature during the balance of the time allotted for the annealing step.

The preparation of the ternary core can be conducted in the presence of a particle growth, nucleation stabilization system (PGNSS). In one aspect, the PGNSS comprises an alkyl amine, for example, an alkyl amine chosen from octylamine, nonylamine, decylamine, undecylamine, dodecylamine (laurylamine), tridecylamine, tetradecylamine (myristyl amine), pentadecylamine, hexadecylamine (palmitylamine), septadecylamine, octadecylamine, and the like. In addition, unsaturated amines can be used in this aspect, for example, an amine chosen from Δ²-dodecenylamine, (Z)-Δ⁹-tetradecenylamine, (Z)-Δ⁹-hexadecenylamine, (Z)-Δ⁹-octadecenylamine (oleylamine), (Z,Z)-Δ^{9,12}-octadecadienylamine (linoleylamine), (Z,Z,Z)-Δ^{9,12,15}-octadecatrienylamine (linolenylamine), (Z)-Δ¹¹-eicosenylamine, (Z,Z,Z)-Δ^{5,8,11}-eicosatrienylamine, and (Z)-Δ¹³-docosenylamine.

The nanoparticle ternary cores can be formed in the presence of one or more coordinating solvents. The choice of coordinating solvent can affect the final properties of the continuously photoluminescent nanoparticles. Coordinating solvents serve several purposes, for example, they coat the ternarycore with a uniform layer thereby removing the maximum of dangling electron bonds/surface states that are responsible for fluorescence trapping and photooxidation, they are capable of solubilizing the formed ternary cores, and because of their relatively high boiling points, allow formation for the ternary cores at high temperatures, for example, from about 270° C. to about 300° C.

Among the different types of coordinating solvents that can be used are alkylphosphines, alkylphosphine oxides, alkylphosphites, alkylphosphates, alkylamines, alkylphosphonic acids, alkylethers, and the like. Solvents suitable for use in preparing the disclosed ternary cores include solvents chosen from trioctylphosphine, tributylphosphine, tri(dodecyl)-phosphine, trioctylphosphine oxide, dibutyl-phosphite, tributyl phosphite, trioctadecyl phosphite, trilauryl phosphite, tris(tridecyl) phosphite, triisodecyl phosphite, bis(2-ethylhexyl)phosphate, tris(tridecyl) phosphate, hexadecylamine, oleylamine, octadecylamine, bis(2-ethylhexyl)amine, octylamine, dioctylamine, trioctylamine, dodecylamine (laurylamine), didodecylamine, tridodecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, dioctylether, dioctyl ether/octyl ether, dodecyl ether, hexadecyl ether, octadecyl ether, and octadecene.

Preparation of CdₓZn₁₋ₓSe/ZnSe, CdₓZn₁₋ₓSe/ZnS, and CdₓZn₁₋ₓSe/ZnSe,S Nanoparticles

Step (c) relates to shelling of the CdₓZn₁₋ₓSe ternary cores to form CdₓZn₁₋ₓSe/ZnSe, CdₓZn₁₋ₓSe/ZnS, and CdₓZn₁₋ₓSe/ZnSe,S nanoparticles.

The disclosed process comprises formation of CdₓZn₁₋ₓSe/ZnSe, CdₓZn₁₋ₓSe/ZnS, or CdₓZn₁₋ₓSe/ZnSe,S nanoparticles comprising:
i) providing a source of a CdₓZn₁₋ₓSe ternary core;
ii) providing a source of ZnSe, ZnS, or an admixture thereof;
iii) combining the source from step (i) with the source from step (ii); and
iv) forming nanoparticles.

In one aspect the disclosed process comprises formation of CdₓZn₁₋ₓSe/ZnSe nanoparticles comprising:
i) providing a source of a CdₓZn₁₋ₓSe ternary core;
ii) providing a source of ZnSe;
iii) combining the source of CdₓZn₁₋ₓSe with the source of ZnSe at a temperature T⁵; and
iv) forming CdₓZn₁₋ₓSe/ZnSe nanoparticles.

In one example of this aspect, the disclosed process comprises formation of CdₓZn₁₋ₓSe/ZnSe nanoparticles comprising:
i) providing a source of a CdₓZn₁₋ₓSe ternary core in the presence of an alkylphosphine oxide coordinating solvent;
ii) providing a source of ZnSe in an alkylphosphine coordinating solvent;
iii) combining the source of CdₓZn₁₋ₓSe with the source of ZnSe at a temperature of from about 150° C. to about 210° C. to form shelled ternary cores; and
iv) cooling the shelled ternary cores to an annealing temperature that is at least about 10° C. lower than the temperature in step (iii) thereby forming CdₓZn₁₋ₓSe/ZnSe nanoparticles.

In another aspect the disclosed process comprises formation of CdₓZn₁₋ₓSe/ZnS nanoparticles comprising:
i) providing a source of a CdₓZn₁₋ₓSe ternary core;
ii) providing a source of ZnS;
iii) combining the source of CdₓZn₁₋ₓSe with the source of ZnS at a temperature T⁵; and
iv) forming CdₓZn₁₋ₓSe/ZnS nanoparticles.

In one example of this aspect, the disclosed process comprises formation of CdₓZn₁₋ₓSe/ZnS nanoparticles comprising:
i) providing a source of a CdₓZn₁₋ₓS ternary core in the presence of an alkylphosphine oxide coordinating solvent;
ii) providing a source of ZnS in an alkylphosphine coordinating solvent;
iii) combining the source of CdₓZn₁₋ₓSe with the source of ZnS at a temperature of from about 150° C. to about 210° C. to form shelled ternary cores; and
iv) cooling the shelled ternary cores to an annealing temperature that is at least about 10° C. lower than the temperature in step (iii) thereby forming CdₓZn₁₋ₓSe/ZnS nanoparticles.

In a further aspect the disclosed process comprises formation of CdₓZn₁₋ₓSe/ZnSe,S nanoparticles comprising:
i) providing a source of a CdₓZn₁₋ₓSe ternary core;
ii) providing a source of ZnSe;
iii) providing a source of ZnS;
iv) combining the source of ZnSe and ZnS to form an admixture;
v) combining the source of CdₓZn₁₋ₓSe with the admixture from step (iv) at a temperature T⁵; and
iv) forming CdₓZn₁₋ₓSe/ZnSe,S nanoparticles.

In one example of this aspect, the disclosed process comprises formation of CdₓZn₁₋ₓSe/ZnSe,S nanoparticles comprising:
i) providing a source of a CdₓZn₁₋ₓSe ternary core in the presence of an alkylphosphine oxide coordinating solvent;
ii) providing an admixture of ZnSe and ZS in an alkylphosphine coordinating solvent;
iii) combining the source of CdₓZn₁₋ₓSe with the admixture of ZnSe and ZnS at a temperature of from about 150° C. to about 210° C. to form shelled ternary cores; and
iv) cooling the shelled ternary cores to an annealing temperature that is at least about 10° C. lower than the temperature in step (iii) thereby forming CdₓZn₁₋ₓSe/ZnSe,S nanoparticles.

Step (c) encompasses shelling the CdₓZn₁₋ₓSe ternary core with ZnSe, ZnS, or a mixture thereof thereby forming continuously photoluminescent nanoparticles having the formula CdₓZn₁₋ₓSe/ZnSe, CdₓZn₁₋ₓSe/ZnS, or CdₓZn₁₋ₓSe/ZnSe,S.

### Compositions

Disclosed are nanoparticle compositions and compositions comprising nanoparticles. It is understood that the disclosed compositions can be used in connection with the disclosed methods.

### Core

The core is comprised of cadmium, zinc, and selenium in the stoichiometry CdₓZn₁₋ₓSe. Unlike the cores of non-continuously photoluminescent quantum dots (i.e., blinking quantum dots) the core of the disclosed quantum dots comprises a spectrum or continuous gradient of cadmium composition from the very inner core to the outer boundary of the ternary core. For example, the ternary CdₓZn₁₋ₓSe core is not homogeneous in its composition, but instead the center comprises predominately CdSe whereas the outer layers of the core are predominately ZnSe. This affords a gradual, continuous transition from CdSe to ZnSe. The effect of this gradual, continuous transition is to relieve the mismatch between the core and shell and to attenuate the interface strain that has been observed to accumulate dramatically with increasing shell thickness. In addition, atom misfits and gaps are drastically reduced. Therefore, the properties of the quantum dot core can be adjusted by varying the stoichiometry of the ternary CdₓZn₁₋ₓSe core. As such the index x can be from greater than about 0.001 to less than about 0.999 depending upon the properties desired by the user.

The heterogeneous ternary cores disclosed herein are obtained by adding the sources of zinc and selenium in a multiple step-wise alternating process. For example, during formation of the ternary core, to a CdSe binary core is added an amount of a source of zinc and an amount of a source of selenium in either order. In yet another example, an amount of a source of zinc and an amount of a source of selenium are added at the same time. The additions of Zn and Se can be made at intervals of 1, 15, 30 seconds, 1, 5, 10, 20, 30, 45, minutes, and 1 hour. In addition, the addition times specified above include all integers between the times and all fractions of those times, for seconds, minutes and hours. The process is then repeated from 1 to 4 (or more) times depending upon the desired size and properties of the final, shelled nanoparticle. Because the first additions of zinc and selenium have more time to alloy with the CdSe core, these atoms of zinc and selenium will be able to migrate further toward the center of the forming core than subsequent additions of zinc and selenium that will have less time to fully disperse within the forming ternary core, thereby forming a continuous concentration gradient of zinc atoms.

By contrast, Zhong et al. (See Zhong, X. et al., “Composition-Tunable Zn₁₋ₓCdₓSe Nanocrystals with High Luminescence and Stability,” JACS, (2003) 125, 8589-8594) report homogeneous ternary cores wherein the forming ternary cores are held at the annealing temperature until there is no further shift in the photoluminescence peak. The lack of further change in the photoluminescence peak is a signal that a fully homogeneous ternary core has formed. Further, Zhong et al. add alternatively the sources of zinc and selenium, after which the forming ternary cores are held until homogeneous. These ternary cores do not afford the continuous gradient in composition of the disclosed ternary cores wherein there is a progression of ternary core composition from cadmium rich centers to zinc rich outer atomic layers.

In one aspect of the disclosed nanoparticle cores, the index x is from about 0.01 to about 0.99. In a further aspect, the index x is from about 0.1 to about 0.7. In another aspect, the index x is from about 0.2 to about 0.7. In a yet further aspect, the index x is from about 0.25 to about 0.7. In a still further aspect, the index x is from about 0.25 to about 0.55. However, the index x can have any fractional value above about 0.001 to less than about 0.999.

Specific examples of the disclosed quantum dots include Cd_{0.1}Zn_{0.9}Se, Cd_{0.15}Zn_{0.85}Se, Cd_{0.2}Zn_{0.8}Se, Cd_{0.25}Zn_{0.75}Se, Cd_{0.3}Zn_{0.7}Se, Cd_{0.35}Zn_{0.65}Se, Cd_{0.4}Zn_{0.6}Se, Cd_{0.45}Zn_{0.55}Se, Cd_{0.5}Zn_{0.5}Se, Cd_{0.55}Zn_{0.45}Se, Cd_{0.6}Zn_{0.4}Se, Cd_{0.65}Zn_{0.35}Se, and Cd_{0.7}Zn_{0.3}Se.

The disclosed nanoparticles typically have a quantum efficiency greater than about 30%. In one aspect, the quantum efficiency is greater than about 40%. In another aspect, the quantum efficiency is greater than about 50%. In a further aspect, the quantum efficiency is greater than about 60%. In a yet further aspect, the quantum efficiency is greater than about 70%.

CdₓZn₁₋ₓSe/ZnSe Nanoparticles

In one aspect of the disclosed process, a source of CdₓZn₁₋ₓSe ternary cores is combined with a source of ZnSe at a temperature sufficient to form a ZnSe shell over the ternary cores. The admixture containing the sources of zinc and selenium is typically prepared before hand by combining a source of zinc with a source of selenium. These ingredients are combined at a temperature below that temperature where the reagents would react with one another and wherein the reagents are thermally stable. The ratio of the zinc to selenium can be from about a 10:1 excess of zinc to about a 1:10 excess of selenium. Other iteration comprises from about 5:1 to about 1:1 zinc to selenium, wherein the zinc is equal to the amount of selenium or is present in an excess amount. Another iteration comprises from about 3:1 to about 1:1 zinc to selenium, wherein the zinc is equal to the amount of selenium or is present in an excess amount. A further iteration comprises from about 1:1 to about 1:5 zinc to selenium, wherein the selenium is equal to the amount of zinc or is present in an excess amount. A yet further iteration comprises from about 1:1 to about 1:3 zinc to selenium, wherein the selenium is equal to the amount of zinc or is present in an excess amount. A still further iteration comprises a ratio of zinc to selenium of about 1:1.

Without wishing to be bound by theory, because the formation of the ZnSe shell is conducted at a temperature below the temperature at which further annealing of the ternary core can take place, the formulator can take advantage of several techniques described herein for forming a suitable outer nanoparticle shell. A first aspect relates to rapid addition of the shell forming material with concomitant lowering of the temperature to at least 10° C. lower than the addition temperature. Addition of the reagents in this manner yields nanoparticles having a narrow particle size distribution and a suitable passification layer.

Also without wishing to be bound by theory, addition of the sources of zinc and selenium as an admixture with slow addition, also leads to continuously photoluminescent nanoparticles. The passification layer, however, varies from that which is formed by the rapid addition method, but the nanoparticles formed from either the fast addition or the slow addition can be adopted for use in the disclosed biological methods.

Without wishing to be limited by theory, the formulator can select the various combinations of ternary cores and shells. In a first aspect, the ternary core comprises a continuous gradient of cadmium and zinc atoms from the center of the core to the outside edge. What is meant by continuous gradient is that the concentration of cadmium atoms at or near the core is approximately equal to the concentration of zinc atoms near the outside edge. However, considering the geometry of a nearly spherical ternary core, more atoms of zinc will necessarily need to be present in the overall ternary core to achieve a continuous gradient. This continuous gradient can then be combined with various ZnSe, ZnS, or ZnSe,S shells as disclosed herein. In one iteration, sufficient zinc and selenium and/or sulfur are added to form a single molecular layer over the core. In another iteration, sufficient zinc and selenium and/or sulfur are added to form two molecular layers over the core. In a further iteration, sufficient zinc and selenium and/or sulfur are added to form three molecular layers over the core. In a still further iteration, sufficient zinc and selenium and/or sulfur are added to form four molecular layers over the core. In a yet further iteration, sufficient zinc and selenium and/or sulfur are added to form five molecular layers over the core.

In addition to the number of ZnSe shell layers present, the diameter of the ternary core can vary from about 1 nanometer to about 100 nanometers. In one aspect, CdₓZn₁₋ₓSe ternary cores having an average diameter of from about 2 nanometers to about 5 nanometers can be shelled with from one to five molecular layers of ZnSe. In a further aspect, CdₓZn₁₋ₓSe ternary cores having an average diameter of from about 3.5 nanometers to about 5 nanometers can be shelled with from one to three molecular layers of ZnSe. The selected ternary cores can have a continuous linear gradient of cadmium and zinc or a continuous non-linear gradient depending upon the final nanoparticle properties desired by the formulator.

Without wishing to be limited by theory, the selection of the ternary core and shell provide different potential energy barriers for the formation of electron-hole pairs and therefore the energy to produce photoluminescence. Advantage can be taken of the non-homogeneous ternary cores to provide the potential for continuous photoluminescence whereas the core provides a means for modulating photo emission. The non-homogenous core provides a gradual potential energy slope for the photo emission instead of a discrete “energy wall” that exists in homogeneous cores that are subsequently shelled. This gradual potential energy slope allows the formulator to combine ternary cores have varying sizes and compositions with shells of varying compositions and thicknesses to form continuously photoluminescent nanoparticles having a wide array of physical properties and biological systems compatibility.

One convenient source of zinc includes di-alkylzinc reagents, for example, diethylzinc. A convenient source of selenium includes tri-alkylphosphine selenides, for example, tri-n-octylphosphine selenide. However, the formulator can use any suitable source of zinc and selenium that can be compatibly pre-mixed and that is stable at temperatures below the shelling temperature range.

The sources of zinc and selenium are combined with the ternary core at a shelling temperature, T⁵, from about 150° C. to about 210° C. In one aspect, the shelling temperature is from about 150° C. to about 200° C. In another aspect, the shelling temperature is from about 160° C. to about 210° C. In a further aspect, the shelling temperature is from about 170° C. to about 200° C. In yet a further aspect, the shelling temperature is from about 180° C. to less than about 200° C. In a still further aspect, the shelling temperature is from about 185° C. to about 195° C. However, the shelling temperature can have any discrete temperature value, for example, 180° C., 181° C., 182° C., 183° C., 184° C., 185° C., 186° C., 187° C., 188° C., 189° C., and the like. In one example, the shelling is conducted at 190° C. In another aspect, the shelling temperature can be varied during the shelling process, for example, a temperature ramp from less than about 210° C. to about 150° C. Or alternatively, a ramp from lower temperature to higher temperature, for example, a temperature ramp from about 150° C. to less than about 210° C. The temperature ramp can be accomplished at any rate, for example, from about 0.1° C./minute to about 10° C./minute. In addition, the ramp may take place during any time interval of the shelling process, for example, a shelling step that is held at a first temperature for a predetermined period and then ramped to a higher or lower temperature during the balance of the time allotted for the shelling step.

Step (c) can further comprise one or more solvents as described herein above, or one or more reagents that can serve as part of a shell-forming stabilization system. These ingredients include alkylamines, such as octylamine, nonylamine, decylamine, undecylamine, dodecylamine (laurylamine), tridecylamine, tetradecylamine (myristyl amine), pentadecylamine, hexadecylamine (palmitylamine), septadecylamine, octadecylamine, and the like. In addition, unsaturated amines can be used in this aspect, for example, an amine chosen from Δ²-dodecenylamine, (Z)-Δ⁹-tetradecenylamine, (Z)-Δ⁹-hexadecenylamine, (Z)-Δ⁹-octadecenylamine (oleylamine), (Z,Z)-Δ^{9,12}-octadecadienylamine (linoleylamine), (Z,Z,Z)-Δ^{9,12,15}-octadecatrienylamine (linolenylamine), (Z)-Δ⁹-eicosenylamine, (Z,Z,Z)-Δ^{5,8,11}-eicosatrienylamine, and (Z)-Δ¹³-docosenylamine. Other suitable reagents may include alkylphosphonic acids, such as hexylphosphonic acid, heptylphosphonic acid, octylphosphonic acid, nonylphosphonic acid, decylphosphonic acid, undecylphosphonic acid, and dodecylphsophonic acid. Still other solvents include alkylphosphines, such as trioctylphosphine and tributylphosphine, and alkylphosphine oxides, such as tri-n-octylphosphine oxide.

Capping ternary cores with a semiconductor shell increases the photoluminescence efficiency of the ensemble by up to an order of magnitude. The disclosed shells provide an energetic barrier isolating the photo-excited electron from harmful surface defects thereby improving the surface quality of the final nanoparticle. The shell also help to protect the surface of the nanoparticle from harmful photo-oxidative processes by providing an effective barrier to oxygen diffusion.

Once the shell forming ingredients have been added and held at the shelling temperature (T⁵) for a sufficient time, the temperature is lowered to an annealing temperature, T⁶. The nanoparticles can be annealed at a temperature, T⁶, that is at least 10° C. lower that the final shelling temperature. In one aspect, the annealing temperature is from about 140° C. to about 200° C. In another aspect, the annealing temperature is from about 150° C. to about 190° C. In a further aspect, the annealing temperature is from about 160° C. to about 180° C. In yet a further aspect, the annealing temperature is from about 170° C. to about 180° C. However, the annealing temperature can have any discrete temperature value, for example, 180° C., 181° C., 182° C., 183° C., 184° C., 185° C., 186° C., 187° C., 188° C., 189° C., and the like. In one example, the annealing is conducted at 180° C.

The final nanoparticles can be isolated by precipitation, for example, by adding a solvent in which the nanocrystals are non-soluble, inter alia, methanol, ethanol, acetone, and the like. Alternatively the nanoparticles can be separated by size selective precipitation with a solvent, for example, methanol. The nanoparticles can be isolated by filtration or centrifugation.

Nanoparticles having the formula CdₓZn₁₋ₓSe/ZnS can be prepared by shelling under the above described conditions but by substituting the source of selenium with a source of sulfur. Convenient sources of sulfur include bis(trimethylsilyl)sulfide.

Combining the steps described herein above for forming CdₓZn₁₋ₓSe/ZnSe nanoparticles, the process comprises:
a) providing a source of CdSe nanoparticles;
b) providing a source of zinc capable of reacting with the CdSe binary core;
c) providing a source of selenium capable of reacting with the CdSe binary core;
d) adding at a temperature sufficient to form a ternary core the source of zinc;
e) adding at a temperature sufficient to form a ternary core the source of selenium;
f) repeating step (d) and step (e);
g) growing the CdₓZn₁₋ₓSe ternary cores;
h) providing a source of Zn capable of forming a nanoparticle shell;
i) providing a source of Se capable of forming a nanoparticle shell;
j) combining the sources from step (h) and step (i) to form an admixture;
k) adding the admixture from step (j) to the CdₓZn₁₋ₓSe ternary cores formed in step (g) to form nanoparticles.

Combining the steps described herein above for forming CdₓZn₁₋ₓSe/ZnS nanoparticles, the process comprises:
a) providing a source of CdSe nanoparticles;
b) providing a source of zinc capable of reacting with the CdSe binary core;
c) providing a source of selenium capable of reacting with the CdSe binary core;
d) adding at a temperature sufficient to form a ternary core the source of zinc;
e) adding at a temperature sufficient to form a ternary core the source of selenium;
f) repeating step (d) and step (e);
g) growing the CdₓZn₁₋ₓSe ternary cores;
h) providing a source of Zn capable of forming a nanoparticle shell;
i) providing a source of S capable of forming a nanoparticle shell;
j) combining the sources from step (h) and step (i) to form an admixture;
k) adding the admixture from step (j) to the CdₓZn₁₋ₓSe ternary cores formed in step (g) to form nanoparticles.

Combining the steps described herein above for forming CdₓZn₁₋ₓSe/ZnSe,S nanoparticles, the process comprises:
a) providing a source of CdSe nanoparticles;
b) providing a source of zinc capable of reacting with the CdSe binary core;
c) providing a source of selenium capable of reacting with the CdSe binary core;
d) adding at a temperature sufficient to form a ternary core the source of zinc;
e) adding at a temperature sufficient to form a ternary core the source of selenium;
f) repeating step (d) and step (e);
g) growing the CdₓZn₁₋ₓSe ternary cores;
h) providing a source of Zn capable of forming a nanoparticle shell;
i) providing a source of Se capable of forming a nanoparticle shell;
j) providing a source of S capable of forming a nanoparticle shell;
k) combining the sources from step (h), step (i), and step (j) to form an admixture;
l) adding the admixture from step (k) to the CdₓZn₁₋ₓSe ternary cores formed in step (g) to form nanoparticles.

One aspect relates to CdₓZn₁₋ₓSe/ZnSe, CdₓZn₁₋ₓSe/ZnS, and CdₓZn₁₋ₓSe/ZnSe,S nanoparticles having a tri-n-alkylphosphine oxide passification layer, for example, tri-n-octylphosphine oxide, tri-n-decylphosphine oxide, and tri-n-tetradecylphosphine oxide passification layer. A further aspect relates to nanoparticles having a linear alkylamine passification layer, for example, a dodecylamine, tetradecylamine, hexadecylamine, or octadecylamine passification layer.

### Passification Layer

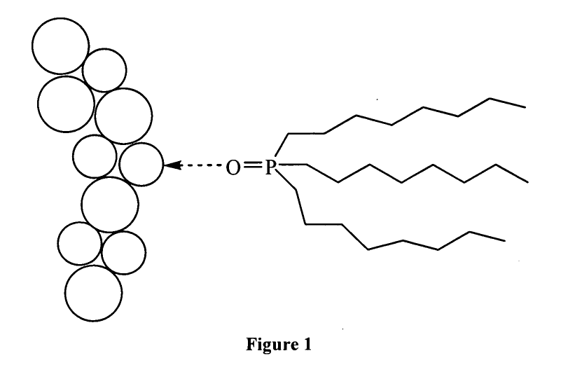

One aspect of the disclosed process provides nanoparticles having a passification layer. This passification layer comprises, for example, stearic acid, oleic acid, octylamine, tetradecylamine, tri-n-octylphosphine, tri-n-octylphosphine oxide, hexadecylamine, and the like. The passification layer serves to help define the hydrodynamic diameter and acts to influence the ability of the nanoparticles to function as either a biological probe or to facilitate entry of the nanoparticle into a cellular structure. For example, the quantum nanoparticles formed in Example 2 herein comprise an outer coating of tri-n-octylphosphine oxide. FIG. 1 depicts a molecule of tri-n-octylphosphine oxide conjugated to an atom on the surface of a nanoparticle shell. This coating can comprise more or less of tri-n-octylphosphine oxide depending upon the amount of tri-n-octylphosphine oxide that is present during the process.

In one aspect, relating to ZnSe shells, the disclosed process comprises:
a) forming a CdSe binary core by combining a source of cadmium and selenium at a temperature sufficient to form a CdSe binary core;
b) adding to the CdSe binary core formed in step (a) in an alternating manner, a source of zinc then a source of selenium at a temperature sufficient for the zinc and selenium to react with the CdSe binary core, wherein the addition of zinc and selenium is repeated at least once more, to form a CdₓZn₁₋ₓSe ternary core wherein further 0.001<x<0.999; and
c) adding to the ternary core formed in step (a) an admixture of a source of zinc and selenium at a temperature that forms a shell over the ternary core thereby forming a nanoparticle having the formula CdₓZn₁₋ₓSe/ZnSe wherein 0.001<x<0.999.

In another aspect, the disclosed processes comprise:
a) first forming a CdSe binary cores by:
   i) combining a source of Cd in a form suitable for forming a binary core and a source of Se in a form suitable for forming a binary core at a temperature sufficient to initiate formation of a CdSe binary core; and
   ii) forming the CdSe binary cores;
b) forming a CdₓZn₁₋ₓSe ternary core by:
   i) providing a source of a CdSe binary core;
   ii) providing a source of zinc capable of reacting with the CdSe binary core;
   iii) providing a source of selenium capable of reacting with the CdSe binary core;
   iv) adding at a temperature sufficient to form a ternary core the source of zinc;
   v) adding at a temperature sufficient to form a ternary core the source of selenium;
   vi) repeating step (iv) and step (v) at least one additional time; and
   vii) thereby forming the CdₓZn₁₋ₓSe cores; and
c) forming a CdₓZn₁₋ₓSe/ZnSe nanoparticle by:
   i) providing a source of a CdₓZn₁₋ₓSe ternary core;
   ii) providing a source of zinc;
   iii) providing a source of selenium;
   iv) combining the source from step (i) with the sources from step (ii) and step (iii); and
   v) forming nanoparticles.

A further aspect relates to a process for forming a CdₓZn₁₋ₓSe/ZnSe nanoparticle, comprising:
a) providing a source of CdSe nanoparticles;
b) alternatively treating the CdSe nanoparticles with a reactive form of zinc then a reactive form of selenium at a temperature sufficient to form a CdₓZn₁₋ₓSe ternary core, wherein the zinc and selenium are added alternatively at least twice; and
c) adding to the ternary core formed in step (b) an admixture containing a source of zinc and selenium in a reactive form at a shell forming temperature to form a nanoparticle having the formula CdₓZn₁₋ₓSe/ZnSe;

wherein 0.001<x<0.999.

A yet further aspect relates to a process for forming a CdₓZn₁₋ₓSe/ZnSe nanoparticle, comprising:
a) providing a source of CdSe nanoparticles;
b) alternatively treating the CdSe nanoparticles with a reactive form of zinc then a reactive form of selenium at a temperature from about 270° C. to about 300° C. to form a CdₓZn₁₋ₓSe ternary core, wherein the zinc and selenium are added alternatively at least twice; and
c) adding to the ternary core formed in step (b) an admixture containing a source of zinc and selenium in a reactive form at a temperature of at least 60° C. lower (i.e., 150° C. to 210° C.) than the temperature of step (b) to form a nanoparticle having the formula CdₓZn₁₋ₓSe/ZnSe;

wherein 0.001<x<0.999.

A still further aspect relates to a process for forming a CdₓZn₁₋ₓSe/ZnSe nanoparticle, comprising:
a) providing a source of CdSe nanoparticles comprising:
   i) CdSe nanoparticles;
   ii) an amine chosen from octylamine, nonylamine, decylamine, dodecylamine, tetradecylamine, hexadecylamine, and octadecylamine; and
   iii) a solvent chosen from trihexylphosphine oxide, triheptylphosphine oxide, trioctylphosphine oxide, trinonylphosphine oxide, tridecylphosphine oxide, triundecylphosphine oxide, and tridodecylphsophine oxide;
b) adding to the source of CdSe from step(a) a composition comprising a source of zinc capable of reaction with the source of CdSe at a temperature of from about 270° C. to about 300° C.;
c) adding to the solution formed in step (b) a composition comprising;
   i) a source of selenium capable or reaction with the source of CdSe; and
   ii) tri-n-octylphosphine;
d) repeating steps (b) and (c) in order at least once more to form a ternary core having the formula CdₓZn₁₋ₓSe/ZnSe wherein 0.001<x<0.999; and
e) adding to the ternary core formed in step (d) a composition comprising:
   i) a reactive form of zinc;
   ii) a reactive form of selenium;
   iii) an amine chosen from octylamine, nonylamine, decylamine, dodecylamine, tetradecylamine, hexadecylamine, and octadecylamine; and
   iv) a solvent chosen from trihexylphosphine oxide, triheptylphosphine oxide, trioctylphosphine oxide, trinonylphosphine oxide, tridecylphosphine oxide, triundecylphosphine oxide, and tridodecylphosphine oxide; at a temperature of at least about 60° C. lower (i.e., 150° C. to 210° C.) than the temperature in steps (b) and (c) wherein the composition is capable of forming a shell over the ternary core to form a nanoparticle.

In one aspect, relating to ZnS shells, the disclosed process comprises:
a) forming a CdSe binary core by combining a source of cadmium and selenium at a temperature sufficient to form a CdSe binary core;
b) adding to the CdSe binary core formed in step (a) in an alternating manner, a source of zinc then a source of selenium at a temperature sufficient for the zinc and selenium to react with the CdSe binary core, wherein the addition of zinc and selenium is repeated at least once more, to form a CdₓZn₁₋ₓSe ternary core wherein further 0.001<x<0.999; and
c) adding to the ternary core formed in step (a) an admixture of a source of zinc and sulfur at a temperature that forms a shell over the ternary core thereby forming a nanoparticle having the formula CdₓZn₁₋ₓSe/ZnS wherein 0.001<x<0.999.

In another aspect, the disclosed processes comprise:
a) first forming CdSe binary cores by:
   i) combining a source of Cd in a form suitable for forming a binary core and a source of Se in a form suitable for forming a binary core at a temperature sufficient to initiate formation of a CdSe binary core; and
   ii) forming the CdSe binary cores;
b) forming a CdₓZn₁₋ₓSe ternary core by:
   i) providing a source of a CdSe binary core;
   ii) providing a source of zinc capable of reacting with the CdSe binary core;
   iii) providing a source of selenium capable of reacting with the CdSe binary core;
   iv) adding at a temperature sufficient to form a ternary core the source of zinc;
   v) adding at a temperature sufficient to form a ternary core the source of selenium;
   vi) repeating step (iv) and step (v) at least one additional time; and
   vii) thereby forming the CdₓZn₁₋ₓSe cores; and
c) forming a CdₓZn₁₋ₓSe/ZnS nanoparticle by:
   i) providing a source of a CdₓZn₁₋ₓSe ternary core;
   ii) providing a source of zinc;
   iii) providing a source of sulfur;
   iv) combining the source from step (i) with the sources from step (ii) and step (iii); and
   v) forming nanoparticles.

A further aspect relates to a process for forming a CdₓZn₁₋ₓSe/ZnS nanoparticle, comprising:
a) providing a source of CdSe nanoparticles;
b) alternatively treating the CdSe nanoparticles with a reactive form of zinc then a reactive form of selenium at a temperature sufficient to form a CdₓZn₁₋ₓSe ternary core, wherein the zinc and selenium are added alternatively at least twice; and
c) adding to the ternary core formed in step (b) an admixture containing a source of zinc and sulfur in a reactive form at a shell forming temperature to form a nanoparticle having the formula CdₓZn₁₋ₓSe/ZnS;

wherein 0.001<x<0.999.

A yet further aspect relates to a process for forming a CdₓZn₁₋ₓSe/ZnS nanoparticle, comprising:
a) providing a source of CdSe nanoparticles;
b) alternatively treating the CdSe nanoparticles with a reactive form of zinc then a reactive form of selenium at a temperature from about 270° C. to about 300° C. to form a CdₓZn₁₋ₓSe ternary core, wherein the zinc and selenium are added alternatively at least twice; and
c) adding to the ternary core formed in step (b) an admixture containing a source of zinc and sulfur in a reactive form at a temperature at least 60° C. lower (i.e., 150° C. to 210° C.) than the temperature of step (b) to form a nanoparticle having the formula CdₓZn₁₋ₓSe/ZnS;

wherein 0.001<x<0.999.

A still further aspect relates to a process for forming a CdₓZn₁₋ₓSe/ZnS nanoparticle, comprising:
a) providing a source of CdSe nanoparticles comprising:
   i) CdSe nanoparticles;
   ii) an amine chosen from octylamine, nonylamine, decylamine, dodecylamine, tetradecylamine, hexadecylamine, and octadecylamine; and
   iii) a solvent chosen from trihexylphosphine oxide, triheptylphosphine oxide, trioctylphosphine oxide, trinonylphosphine oxide, tridecylphosphine oxide, triundecylphosphine oxide, and tridodecylphsophine oxide;
b) adding to the source of CdSe from step(a) a composition comprising a source of zinc capable of reaction with the source of CdSe at a temperature of from about 270° C. to about 300° C.;
c) adding to the solution formed in step (b) a composition comprising;
   i) a source of selenium capable of reaction with the source of CdSe; and
   ii) tri-n-octylphosphine;
d) repeating steps (b) and (c) in order at least once more to form a ternary core having the formula CdₓZn₁₋ₓSe/ZnS wherein 0.001<x<0.999; and
e) adding to the ternary core formed in step (d) a composition comprising:
   i) a reactive form of zinc;
   ii) a reactive form of sulfur;
   iii) an amine chosen from octylamine, nonylamine, decylamine, dodecylamine, tetradecylamine, hexadecylamine, and octadecylamine; and
   iv) a solvent chosen from trihexylphosphine oxide, triheptylphosphine oxide, trioctylphosphine oxide, trinonylphosphine oxide, tridecylphosphine oxide, triundecylphosphine oxide, and tridodecylphosphine oxide;
at a temperature of at least about 60° C. lower than the temperature in steps (b) and (c) wherein the composition is capable of forming a shell over the ternary core to form a nanoparticle.

Any of the above aspects can further comprise one or more solvents, coordinating solvents, nucleation modifiers, or surface passification agents.

In the following examples, the amounts of reagents necessary to provide the various desired quantum dot shell molecular layers was determined by using the sizing curves disclosed by Qu, L., “Control of Photoluminescence Properties of CdSe Nanocrystals in Growth,” J. Am. Chem. Soc., (2002), 124, 2049-2055 all of which is incorporated herein by reference.

As disclosed herein above, the ternary cores are shelled with ZnSe, ZS, or ZnSe,S. The thickness of the shell, i.e., the number of molecular layers (ML) can be adjusted by the formulator. The following is an example of a calculation used to determine the amount of shelling reagent necessary to provide a 5 mL shell.

For this example, CdₓZn₁₋ₓSe cores having an average diameter of 3.2 nm (a core radius of 1.6 nm) is used and the shell comprises ZnSe. The thickness of a single ZnSe ML is approximately 0.3 nm. The volume of the shell is given by:

$${V}_{shell} = \frac{4}{3} π [ {( {r}_{core + shell} )}^{3} - {( {r}_{core} )}^{3} ]$$

wherein the radius of the core is 1.6 nm, the radius of the core+shell is 3.1 nm [(5×0.3 nm)+1.6 nm]. The volume of the shell is approximately 107.6 nm³ (1.08×10⁻¹⁹ cm³). To obtain the amount of ZnSe necessary to shell one ternary core:

M_{ZnSe}=(1.08×10⁻¹⁹)×d_{ZnSe}/MW_{ZnSe}=4.04×10⁻²¹ mol

wherein M_{ZnSe} is the number of moles of ZnSe necessary to shell one ternary core with 5 mL's, d_{ZnSe} is the density of ZnSe (5.r2 g/cm³) and MW_{ZnSe} is the molecular weight of ZnSe (144.35 g/mol). Therefore, to shell 100 nmol of ternary shells:

M_{(100)ZnSe}=100 nmol core×6.023×10²³ cores/mol×4.04×10⁻²¹ mol/core=244 μmol

Therefore, 244 μmol of ZnSe is necessary to shell 100 nmol of ternary cores with 5 molecular layers. This can be accomplished by adding 244 μL of a 1M solution of diethylzinc and 244 μL of 1M solution of tri-n-octylphosphine selenide to the ternary cores according to the procedures disclosed herein above.

### Biological Conjugates

In one aspect, the disclosed biological conjugates comprise:
a) continuously photoluminescent nanoparticles comprising:
   i) a ternary core having the formula CdₓZn₁₋ₓSe wherein 0.001<x<0.999; and
   ii) a shell chosen from ZnSe, ZnS, or a mixture thereof; and
b) a biological analyte conjugated thereto.

The disclosed nanoparticles are suitable for use in biological assays, as reporters for biological cellular interactions, and as diagnostic tools. For many of the biological applications described herein below, the ligand which is used to prepare the nanoparticle, inter alia, tri-n-octylphosphine oxide that forms the passification layer, must be exchanged or adapted in order to make the nanoparticle water soluble.

As described herein above, the disclosed nanoparticles comprise a passification layer or coating. The passification can be adjusted by the formulator to meet the precise needs of the formulator. There are two methods disclosed herein for converting hydrophobic nanoparticles to hydrophilic, water soluble nanoparticles. In the first method, the passification layer, for example, tri-n-octylphosphine oxide or hexadecylamine, that coats and protects the outer layer of the final nanoparticle, can be exchanged for a ligand or ligands that is more suitable for the intended use or biological target. One method for exchanging the surface ligands is to dissolve the nanoparticles in a suitable solvent that comprises a large excess of the desired ligand, or simply in a solution of the ligand itself if the ligand is a liquid. For exchanging the hydrophobic ligands typically used to prepare the disclosed nanoparticles, the nanoparticle is dissolved in a suitable solvent in which the new ligand is not soluble and a second solvent containing the desired hydrophilic ligand in a significantly larger quantity is added. The non-miscible liquids are intimately mixed and the nanoparticles will gradually transfer to the second liquid as the ligand exchange occurs. Dialysis or precipitation-redispersion cycles can be used for purification and removing the excess ligands.

A second method for rendering hydrophobic nanoparticles water soluble relates to a process that allows the original passification layer to remain intact. This can be accomplished by adsorption onto the nanoparticle one or more amphiphilic polymers or phospholipids that contain a hydrophobic segment and a hydrophilic segment. Polymers which are suitable for use include polyethylene glycol, alkylamine-modified polyacrylic acid, polyalkyleneoxy-derivatized phospholipids, DL-lactide-co-glycolide-co-polyalkyleneoxy block copolymers, and amphiphilic polyanhydrides. The lipophilic regions of the polymer interact with the lipophilic passification layer thereby extending the hydrophilic region of the polymer outward thereby making the nanoparticle water soluble.

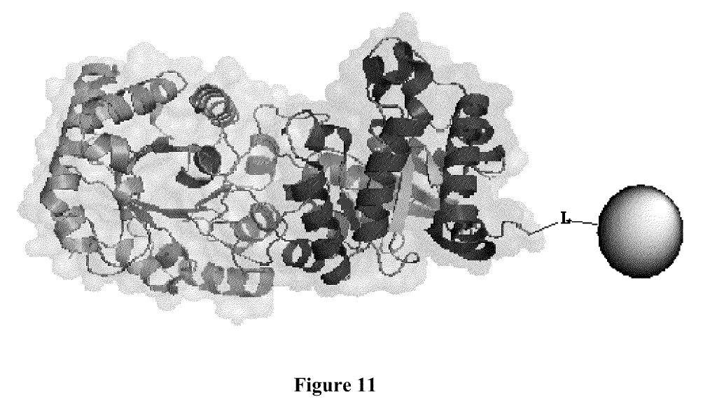

The biological analyte conjugated to the nanoparticle, can be attached to the hydrophilic end of a polymer or phospholipid that is used to form the water soluble nanoparticle. Alternatively, prior to modification of the passification layer, a reactive ligand can be exchanged for a portion of the passification layer and then one end of the reactive ligand can react with the biological analyte to form a linking group. FIG. 11 depicts an enzyme linked by a unit L to a continuously photoluminescent nanoparticle as disclosed herein. As can be seen the tether is connected at the terminus of the peptide chain away from the enzyme's active site so as not to interfere with the activity of the enzyme. The length of the tether can be from 5 to 100 nanometers, depending upon the type of analyte and its function.

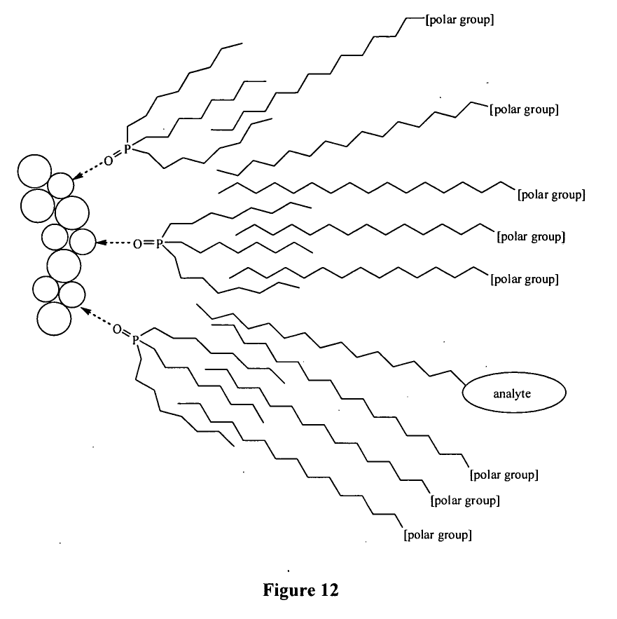

FIG. 12 depicts a portion of the passification layer a water soluble continuously photoluminescent nanoparticle wherein the nanoparticle is made water soluble by forming a bi-layer along the surface of the passification layer and wherein the analyte is conjugated to the nanoparticle by association with a surfactant making up the bilayer.

The nanoparticles can be used as diagnostic screens, for example, as diagnostic assays for cancer. Body fluid, inter alia, blood and urine, are analyzed for the presence of biological markers that indicate the presence of cancerous tissue. The concentration of many of these markers is very low, therefore, the sensitivity of present techniques can miss the presence of a cancer related indicator in many instances. For example, prostate cancer is screened for by measuring the level of prostate-specific antigen. However, many other types of cancers are not yet detected by serum assays. Conjugating one of the disclosed nanoparticles to an antigen specific to a particular type of cancer or tumor cell, allows for the detection of malignancy when the abnormal cells are present in very low concentration and therefore leads to an early detection of the disease.

Whether conjugated to the nanoparticle by a direct chemical linker or through affinity, for example, the biological analyte is attached to an amphiphilic material that associates with the passification layer, and the continuously photoluminescent nanoparticle can be used to track and to monitor the activity of the presence of a biological species.

### Methods of Using Nanoparticles

In one aspect, the invention relates to methods of using nanoparticles. Included herein are methods for adapting the properties of the disclosed continuously photoluminescent nanoparticles to meet the various needs of the formulator or investigator. Thus, the present disclosure further relates to methods of using the disclosed nanoparticles. One aspect relates to a probe comprising one or more continuously photoluminescent nanoparticle having the formula CdₓZn₁₋ₓSe/ZnSe, CdₓZn₁₋ₓSe/ZnS, or CdₓZn₁₋ₓSe/ZnSe,S wherein 0.001<x<0.999 for determining the presence or function of a biological analyte. The biological analyte can comprise one or more of the following amino acids, nucleic acids, saccharides, triglycerides, fatty acids, or organic compounds.

Broadly the methods comprise:
a) conjugating a biological analyte with a continuously photoluminescent nanoparticle to form a tagged analyte;
b) irradiating the tagged analyte; and
c) monitoring the tagged analyte.

The modification of nanoparticles in a manner suitable to render the nanoparticles useful for the herein described biological applications is described in U.S. Pat. No. 6,326,144 B1, issued to Bawendi et al., Dec. 4, 2001, which is incorporated herein by reference in its entirety. The methods for modifying quantum dots as described in U.S. Pat. No. 6,326,144 B1, can be applied to the continuously photoluminescent nanoparticles described herein.

One aspect of the disclosure relates to nanoparticles having an affinity for one or more biological analytes. In one aspect, the nanoparticle is conjugated to a biological analyte in a cell. In a further aspect, the nanoparticle is connected to a biological analyte by a linker. In another aspect, the nanoparticle has affinity for a cellular-active compound.

In a yet further aspect, the nanoparticle has affinity for an organic compound introduced into the cell. In another aspect, the organic compound introduced into the cell is a pharmaceutically active ingredient.

In a still further aspect, the nanoparticle has affinity for a cellular-active compound that is formed within a cell. In a yet still further aspect, the nanoparticle has an affinity for a biological analyte containing amino acids, nucleic acids, saccharides, triglycerides, or fatty acids.

Another aspect of the disclosure relates to a probe for determining the presence or function of a biological analyte. In one aspect, the nanoparticle is conjugated to a biological analyte. In another aspect, the nanoparticle is used to probe a biological analyte containing amino acids, nucleic acids, saccharides, triglycerides, fatty acids, or an organic compound that conjugates with the nanoparticle wherein the nanoparticle becomes conjugated to the analyte. In a further aspect the probe is used to track or determine the presence of an analyte in vivo, in vitro, or ex vivo.

As a method for continuously tracking the interaction of a biological analyte and a biological effector in a cell, the method comprises:

As a method for continuously tracking the interaction of a biological analyte and a biological effector in a cell, the method comprises:
a) forming a biological analyte/nanoparticle conjugate within a cell, wherein the nanoparticle emits continuous photoluminescence at a first wavelength;
b) forming a biological effector/nanoparticle conjugate ex vivo, wherein the nanoparticle emits continuous photoluminescence at a second wavelength;
c) introducing the biological effector/nanoparticle conjugate into the cell containing the biological analyte/nanoparticle conjugate; and
d) monitoring the photoluminescent emission of the conjugates.

Further uses of the continuously photoluminescent nanoparticles include thin-film light emitting devices (LEDs), low-threshold lasers, optical amplifier media for telecommunication networks, for relay of encrypted information.

A non-limiting example of a non-biological method that utilizes the disclosed nanoparticles relates to the transmission of encrypted information. For example, a method of sending encrypted information from a sender to a receiver, comprising:
a) generating at the sender a series of individual photons from a continuously emitting photoluminescent source;
b) directing the series of individual photons through a means for polarizing each photon passing in sequence, wherein the amount that each photon is polarized is pre-determined and known by the receiver; and
c) directing the series of polarized photons to a receiver capable of determining whether the polarized photons are received in their pre-determined sequence.

### Experimental

The following examples are put forth so as to provide those of ordinary skill in the art with a complete disclosure and description of how the compounds, compositions, articles, devices, and/or methods claimed herein are made and evaluated, and are intended to be purely exemplary of the invention and are not intended to limit the scope of what the inventors regard as their invention. Efforts have been made to ensure accuracy with respect to numbers (e.g., amounts, temperatures, etc.), but some errors and deviations should be accounted for. Unless indicated otherwise, parts are parts by weight, temperature is in ° C. or is at ambient temperature, and pressure is at or near atmospheric. All solvents are degassed prior to use in all reactions.

### Example 1

### Comparative

Preparation of Cdse Binary Core

Cadmium oxide (CdO) (0.0514 g, 0.4 mmol) and stearic acid (0.5 g, 1.8 mmol) were added to a 100-mL reaction flask. The flask was de-gassed using a Schlenk tube at 100° C. for 30 minutes after which argon gas was introduced into the flask. The flask was then further heated to 180° C. until a clear colorless solution was obtained. After cooling to room temperature, the flask was transferred to a glove box wherein the remaining steps were performed under inert atmosphere. Tri-n-octylphosphine oxide (6 mL) and n-hexadecylamine (3 mL) were added. The solution was de-gassed using a Schlenk tube at 100° C. for 10 minutes after which argon gas was introduced into the flask. The reaction flask was heated to 300° C. A solution of tri-n-octylphosphine selenide (TOP-Se) was previously prepared by dissolving Se (0.7896 g, 10 mmol) in tri-n-octylphosphine (TOP) (10 mL) at room temperature under an inert atmosphere in a glove box. The tri-n-octylphosphine selenide solution (2 mL) was then rapidly added to the reaction vessel in one aliquot. The reaction vessel is cooled to 260° C. and the CdSe quantum dots are allowed to grow for 10 minutes after which the reaction vessel was cooled to room temperature.

Preparation of CdₓZn₁₋ₓSe Ternary Core

CdSe quantum dots prepared above (3 mL) were transferred to a fresh 100-mL reaction flask. The solution was de-gassed using a Schlenk tube at 100° C. for 10 minutes after which argon gas was introduced into the flask. The reaction flask is then heated to 190° C. A previously prepared solution of zinc selenide (ZnSe) was made in a glove box under inert atmosphere by combining diethyl zinc (138 μL of a 1 M solution in hexane), the previously prepared solution of tri-n-octylphosphine selenide (138 μL) and tri-n-octylphosphine (1 mL). This zinc selenide solution was added at a rate of 10 mL/hr. The amount of ZnSe in this solution was calculated to be an amount sufficient to provide 3 molecular layers of a ZnSe shell. Following addition of the zinc selenide solution, the flask was heated to 300° C. for 30 minutes to allow alloying of the core/shell to occur. The flask was then cooled to room temperature.

Preparation of CdₓZn₁₋ₓSe/ZnSe,S Nanoparticles

An aliquot of the CdₓZn₁₋ₓSe/ZnSe quantum dots prepared above (1.5 mL), tri-n-octylphosphine oxide (3 mL) and n-hexadecylamine (2 mL) were combined in a fresh 100-mL reaction flask under inert atmosphere in a glove box. Using a Schlenk line, the contents of the flask were de-gassed under vacuum at 100° C. for 10 minutes. Argon gas was then introduced into the reaction vessel. The reaction flask was heated to 190° C. A previously prepared solution of ZnSe,S was made by combining diethylzinc (402 μL of a 1 M solution in hexane), the previously prepared solution of tri-n-octylphosphine selenide (134 μL), bis(trimethylsilyl)sulfide (590 μL of a 0.455 M solution in hexane), and tri-n-octylphosphine (2.5 mL) was added slowly to the reaction flask at a rate of 10 mL/hr. When the addition was complete, the flask was cooled to 180° C. and allowed to anneal for 1 hour. The flask was then cooled to room temperature to afford the CdₓZn₁₋ₓSe/ZnSe,S quantum dots.

### Example 2

### Preparation of Cdse Binary Core

Tetradecylphosphonic acid (TDPA) (0.0755 g) was added to a 100-mL flask after which tri-n-octylphosphine oxide (TOPO) (4.55 mL) and n-hexadecylamine (HDA) (3.1 mL) were added under inert atmosphere in a glove box. Using a Schlenk line, the contents of the flask were de-gassed under vacuum at 100° C. for 30 minutes. Argon gas was then introduced into the reaction vessel. A solution of tri-n-octylphosphine selenide (TOP-Se) was previously prepared by dissolving Se (0.7896 g, 10 mmol) in tri-n-octylphosphine (TOP) (10 mL) at room temperature under an inert atmosphere in a glove box. The tri-n-octylphosphine selenide solution (1 mL) was then added to the reaction vessel in one aliquot. The reaction vessel was de-gassed an additional 10 minutes under vacuum then argon gas was introduced into the reaction vessel. The reaction vessel was then heated to 300° C. A solution of cadmium acetate in tri-n-octylphosphine was previously prepared under inert atmosphere in a glove box by adding cadmium acetate (0.06 g) to tri-n-octylphosphine (1.5 mL) with slight heating. This Cd(Ac)₂ in TOP was rapidly added in one portion to the reaction vessel. The reaction vessel is cooled to 260° C. and the CdSe quantum dots are allowed to grow for 6 minutes after which the reaction vessel was cooled to room temperature.

Preparation of CdₓZn₁₋ₓSe Ternary Core

An aliquot of the CdSe quantum dots prepared above was charged to a fresh 100-mL reaction flask. The vessel was held under vacuum until the CdSe quantum dots melted and argon gas was introduced. The flask is heated to 300° C. Eight syringes were previously prepared. Four syringes contained diethylzinc in tri-n-octylphosphine (700 μL) and four syringes contained the previously prepared solution of tri-n-octylphosphine selenide (700 μL). Beginning with a syringe containing diethylzinc, and alternating between diethylzinc and tri-n-octylphosphine selenide, the contents of the syringes were rapidly injected into the reaction solution at intervals of 20 seconds. The flask was held at 300° C. for 3 minutes then cooled to room temperature.

Preparation of CdₓZn₁₋ₓSe/ZnSe Nanoparticles

To a 100-mL flask were added CdₓZn₁₋ₓSe ternary cores (48 nmol of ternary cores having an average diameter of 3.4 nm). The flask is then transferred to a glove box wherein the remaining steps are performed under inert atmosphere. Tri-n-octylphosphine oxide (5.96 mL) and n-hexadecylamine (4.15 mL) were added to the reaction flask. Using a Schlenk tube, the solution is de-gassed at 105° C. for 30 minutes after which argon gas was introduced into the flask. The contents of the reaction flask were then heated to 190° C. A solution of zinc selenide (ZnSe) was prepared before hand by mixing a solution of diethylzinc in hexane (130 μL), tri-n-octylphosphine selenide (169 μL) of the previously prepared 1 M solution, and tri-n-octylphosphine (1 mL). The amount of ZnSe in this solution was calculated to be an amount sufficient to provide 5 molecular layers of a ZnSe shell. The zinc selenide solution was added dropwise over 2-3 seconds. The reaction vessel was cooled to 180° C. and allowed to anneal for 45 minutes after which the reaction vessel is cooled to room temperature to afford the CdₓZn₁₋ₓSe/ZnSe quantum dots.

### Characterization of Continuously Photoluminescent Nanoparticles

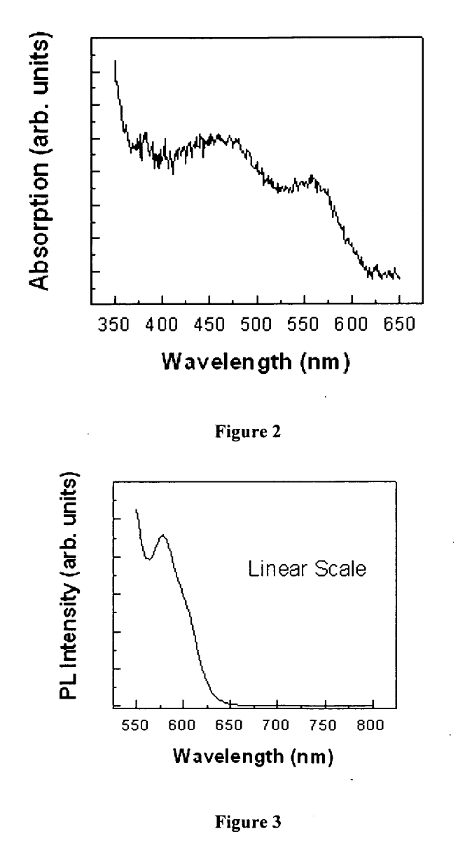

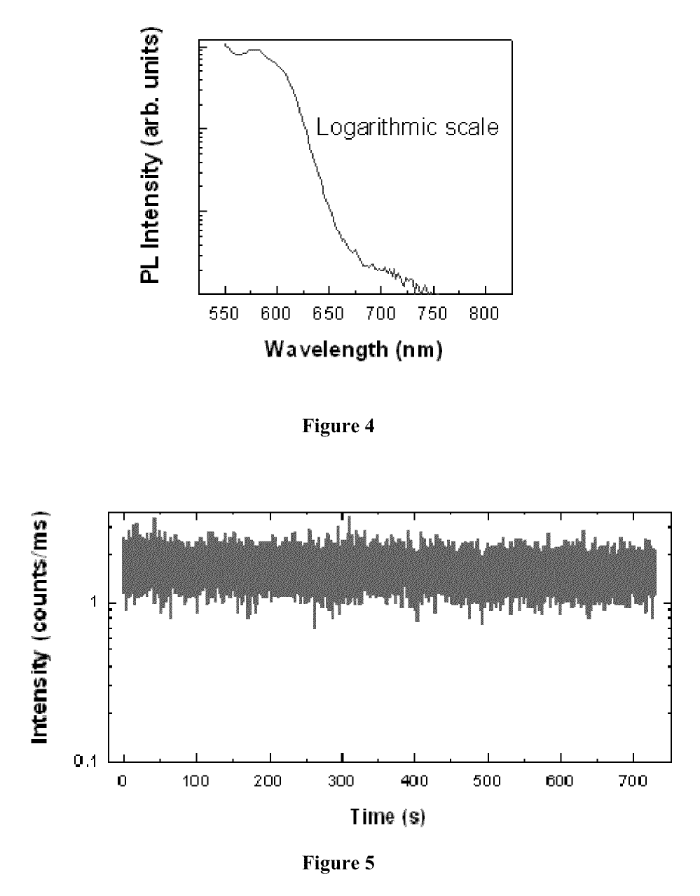

FIG. 2 shows the absorption spectrum of a CdₓZn₁₋ₓSe/ZnSe nanoparticle according to the present disclosure measured as a solution in toluene using a UV/vis/NIR spectrometer. FIGS. 3 and 4 show the photoluminescence spectra of a CdₓZn₁₋ₓSe/ZnSe nanoparticle measured in toluene solution with a fluorometer. The photoluminescence spectra were obtained using 532 nm excitation. FIG. 3 shows a linear plot while FIG. 4 shows a logarithmic plot. Each spectrum indicates a shoulder peak (˜625 nm) appearing to the right of the central one (˜580 nm) and a small tail extending from ˜650 nm to ˜750 nm.

FIG. 5 shows the continuous photoluminescence of a CdₓZn₁₋ₓSe/ZnSe nanoparticle according to the present disclosure. The sample was prepared by spin-casting a diluted solution of nanoparticles in toluene with 1% poly(methyl methacrylate) (PMMA) onto a quartz coverslip. The average distance between nanoparticles embedded within the PMMA film is >5 μm. This solid-film sample was mounted on a confocal scanning optical microscope where the single nanoparticles were excited by a 532 nm continuous wave laser beam focused to the diffraction limit (˜400 nm) by an oil immersion objective (NA=1.5). The typical laser power density used for exciting a single nanoparticle was varied from ˜0.1-10 kW/cm². Optical emissions from a single nanoparticle were collected by the same objective and sent either to a charge coupled device (CCD) attached to a spectrometer for the photoluminescence spectral and imaging measurements, or to a time-correlated single photon counting system for the blinking and anti-bunching measurements.

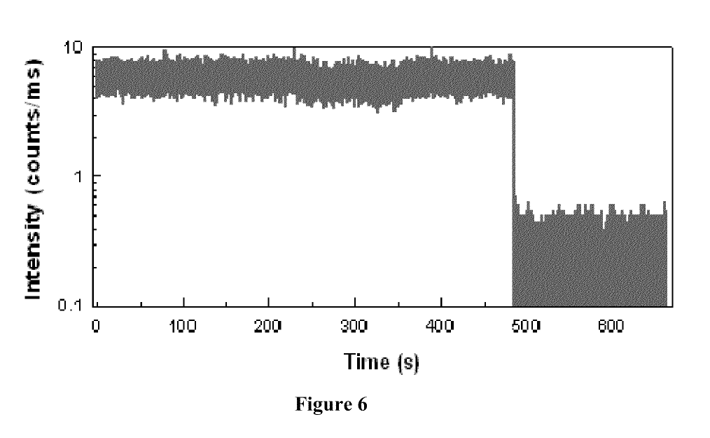

FIG. 5 depicts the photoluminescence intensity versus time trace of one single nanoparticle excited with a laser power density of ˜1 kW/cm². The nanoparticle photoluminescence intensity versus time is recorded approximately 700 s in intervals of 30 ms. No photoluminescence intensity fluctuations were observed on a time scale of 1 ms to several hours. FIG. 6 shows that when the laser power density was further increased to ˜10 kW/cm², only continuous photoluminescence was observed until the nanoparticle became photo-bleached within ˜10-500 s.

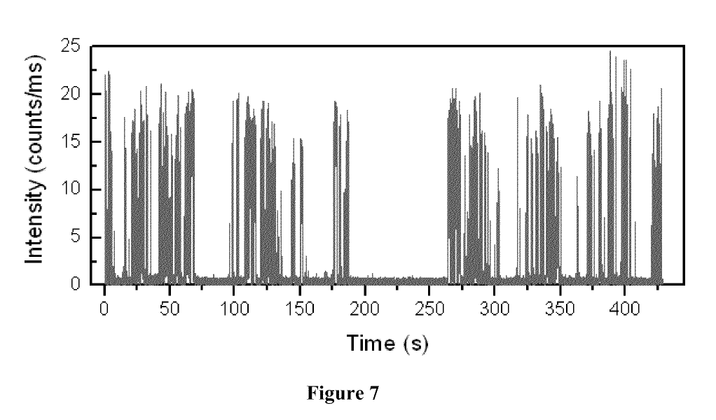

FIG. 7 shows the non-continuous photoluminescence of a single CdSe nanoparticle (Qdot605™ Streptavidin Conjugate available from Invitrogen Corporation). This discontinuous photoluminescence has been ubiquitously observed in all the solid-film colloidal nanoparticle systems previously reported in the literature.

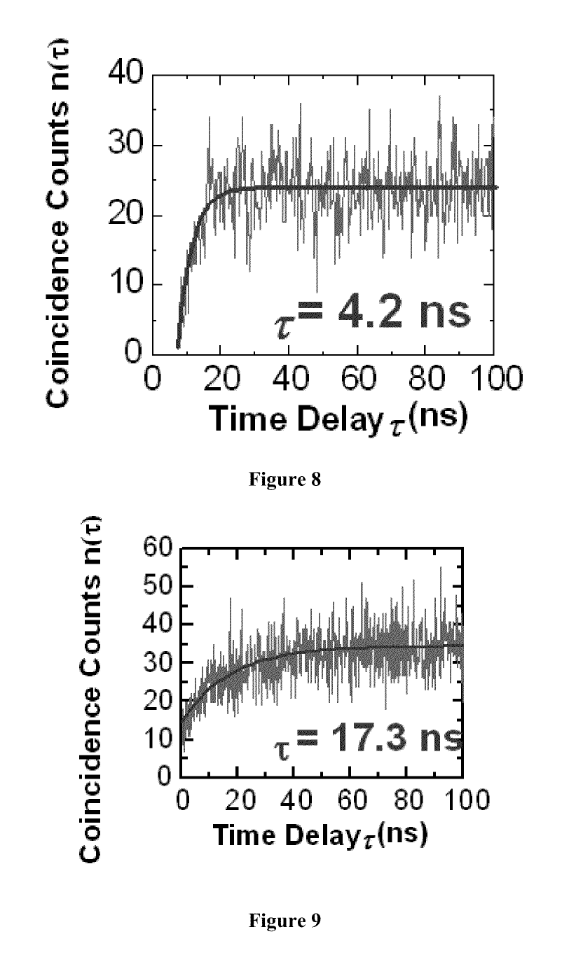

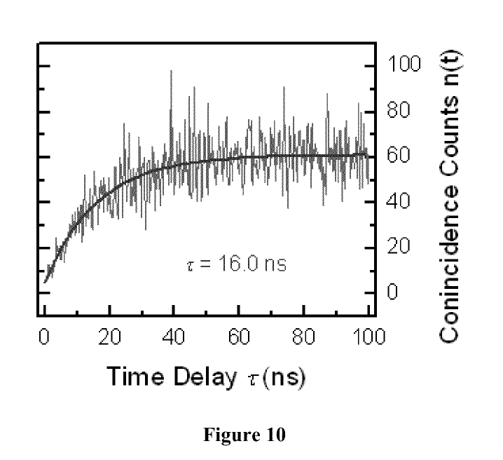

FIG. 8 shows a typical histogram of photon coincidence counts for the time delays between two consecutive photons emitted from a single CdₓZn₁₋ₓSe/ZnSe nanoparticle whose time trace of photoluminescence intensity is depicted in FIG. 5. As depicted, nearly complete photon anti-bunching was detected by the dip (with a count value of ˜1) in coincidences around zero time delay. This measurement of the optical emission provides a method for determining the continuous photoluminescence of the disclosed nanoparticles. This histogram of photon coincidence counts can be fitted very well by a single exponential function with a rise time constant of ˜4.2 ns, which corresponds to the radiative lifetime of a single CdₓZn₁₋ₓSe/ZnSe nanoparticle. FIG. 9 shows the histogram of photon coincidence counts measured for a prior art CdTe nanoparticle. The radiative lifetime was approximately 17.3 ns. FIG. 10 shows the histogram of photon coincidence counts measured for the nanoparticle whose time trace of photoluminescence intensity is depicted in FIG. 7. The absence of a continuous emission is manifested in the fact that these nanoparticles display a discontinuous photoluminescence.

While particular aspects of the present disclosure have been illustrated and described, it would be obvious to those skilled in the art that various other changes and modifications can be made without departing from the spirit and scope of the disclosure. It is therefore intended to cover in the appended claims all such changes and modifications that are within the scope of this disclosure.

What is claimed is:

1) A nanoparticle comprising:
i) a ternary core comprising Cd, Zn and Se; and
ii) a shell comprising Zn and Y, wherein Y is Se or S or a combination thereof,
wherein the Cd and Zn are non-homogenously distributed in the ternary core such that the photoluminescence exhibited by the nanoparticle is continuous as determined by a lack of correlation between fluctuations in photoluminescence intensity over a period of at least 200 seconds.

2) The nanoparticle according to claim 1, wherein the ternary core has the formula:
CdₓZn₁₋ₓSe, wherein 0.001<x<0.999.

3) The nanoparticle according to claim 1, wherein the range of x is selected from the group consisting of all values to the hundredth decimal point between 0.01 to 0.99.

4) The nanoparticle according to claim 2, wherein the ternary core has a formula chosen from Cd_{0.1}Zn_{0.9}Se, Cd_{0.15}Zn_{0.85}Se, Cd_{0.2}Zn_{0.8}Se, Cd_{0.25}Zn_{0.75}Se, Cd_{0.3}Zn_{0.7}Se, Cd_{0.35}Zn_{0.65}Se, Cd_{0.4}Zn_{0.6}Se, Cd_{0.45}Zn_{0.55}Se, Cd_{0.5}Zn_{0.5}Se, Cd_{0.55}Zn_{0.45}Se, Cd_{0.6}Zn_{0.4}Se, Cd_{0.65}Zn_{0.35}Se, and Cd_{0.7}Zn_{0.3}Se.

5) The nanoparticle according to claim 2, wherein the ternary core comprises a continuous gradient of Cd and Zn atoms wherein the first end of the gradient which begins at the center of the ternary core comprises greater than 60%, 70%, 80%, 90 or 100% cadmium atoms and the second end of the gradient which begins at the outside layer of the ternary core comprises greater than 60%, 70%, 80%, 90% or 100% zinc atoms.

6) The nanoparticle of claim 1, wherein the gradient follows a function of all trigonometric functions, polynomials, exponentials, and all sums and products thereof.

7). A composition comprising nanoparticles according to claim 1, wherein the size distribution of the nanoparticles is substantially monodisperse and the average diameter of the nanoparticles is between 1 nm and 100 nm.

8) composition of claim 7, wherein the average diameter of the nanoparticles is between 2 nm and 7 nm.

9) A process for preparing nanoparticles of claim 1, comprising the steps of:
a) providing CdSe binary cores;
b) adding, at least twice, alternately to the cores of a) a source of zinc capable of reacting with the CdSe binary core and a source of selenium capable of reacting with the CdSe binary core at a temperature sufficient to form a ternary core;
c) holding the cores from b) at a temperature and time sufficient for obtaining CdZnSe ternary cores; and
d) adding to the CdZnSe ternary cores a source of Zn and a source of Y to form a nanoparticle comprising a ternary core and a ZnY shell, wherein Y is Se, S or a combination thereof,
wherein the photoluminescence exhibited by the nanoparticle is continuous as determined by a lack of correlation between fluctuations in photoluminescece intensity over a period of at least 200 seconds.

10) The process of claim 9, wherein the CdSe binary cores of step a) are provided in a particle growth, nucleation stabilization system and a coordinating solvent.

11) The process of claim 9, wherein steps a), b) and c) are carried out at a temperature of 270 to 300° C.

12) The process according to claim 9, wherein the source of zinc in step (b) is diethylzinc and the source of selenium in step (b) is tri-n-octylphosphine selenide.

13) The process according to claim 9, wherein step (b) is conducted at a temperature in the range selected from the group consisting of about 280° C. to about 300° C., from about 290° C. to about 295° C.

14) process according to claim 9, wherein step (b) is conducted at a temperature of about 300° C.

15) The process according to claim 9, wherein step (c) is conducted at a temperature in the range selected from the group consisting of about 270° C. to about 290° C., and about 280° C. to about 295° C.

16) The process according to claim 15, wherein the ternary core in step (c) is held for a time selected from the group consisting of from 30 seconds to about 1 hour, from 1 minute to about 10 minutes from 3 minutes to about 7 minutes.

17) The process according to claim 9, wherein the source of zinc in step (d) is diethylzinc.

18) The process according to claim 9, wherein Y in step (d) is Se and the source of Y is tri-n-octylphosphine selenide.

19) The process according to claim 9, wherein Y in step (d) is S and the source of Y is dihydrogen sulfide, bis(alkylsilyl)sulfide or bis(trimethylsilyl)sulfide.

20) The process according to claim 9, wherein step (d) is conducted at a temperature in the ranges selected from the group consisting of from about 150° C. to about 190° C., from about 160° C. to about 180° C., and from about 170° C. to about 180° C.
